(19) United States
(12) Patent Application Publication
(10) Pub. No.: US 2025/0221247 A1
(43) Pub. Date: Jul. 3, 2025

(54) DISPLAY APPARATUS AND METHOD OF MANUFACTURING THE SAME

(71) Applicant: SAMSUNG DISPLAY CO., LTD., Yongin-si (KR)

(72) Inventors: Gwangtaek Lee, Yongin-si (KR); Taewoo Park, Yongin-si (KR)

(21) Appl. No.: 18/985,614

(22) Filed: Dec. 18, 2024

(30) Foreign Application Priority Data
Dec. 27, 2023 (KR) 10-2023-0193405

(51) Int. Cl. H10K 59/80; H10K 102/00

(52) U.S. Cl. CPC H10K 59/871; H10K 2102/311

(57) ABSTRACT

A display apparatus in which a portion of a component attached to a cover window does not detach from the cover window when the display apparatus is folded is provided. The display apparatus includes a display panel that includes display elements, and a cover window disposed above the display panel and that includes a window, a first protective layer, and a second protective layer. The window includes a first non-folded area, a second non-folded area, and a foldable area located between the first non-folded area and the second non-folded area, and a plurality of trenches formed in the foldable area. Depths of a trench formed adjacent to the first non-folded area and a trench formed adjacent to the second non-folded area are greater than a depth of a trench formed in a central area of the foldable area.

### CROSS-REFERENCE TO RELATED APPLICATION

This application claims priority under 35 U.S.C. § 119 from Korean Patent Application No. 10-2023-0193405, filed on Dec. 27, 2023 in the Korean Intellectual Property Office, the contents of which are herein incorporated by reference in their entirety.

### TECHNICAL FIELD

One or more embodiments are directed to a display apparatus, and more particularly, to a display apparatus in which a portion of a component attached to a cover window does not detach from the cover window when the display apparatus is folded, and a method of manufacturing the display apparatus.

### DISCUSSION OF THE RELATED ART

Display apparatuses can be formed by combining various members with each other. Specifically, display apparatuses can be formed by combining a display panel that includes a display element with a cover window that protects the display panel and combining the cover window with a protective film that protects the cover window.

Display apparatuses can be utilized as various electronic apparatuses. For example, display apparatuses may be mobile electronic apparatuses such as smartphones. Electronic apparatuses may be foldable electronic apparatuses in which a portion of a display surface thereof is folded to increase the area of a display area thereof while reducing an overall size.

However, a portion of a component attached to a cover window of such a display apparatus can detach from the cover window when the display apparatus is folded.

### SUMMARY

One or more embodiments include a display apparatus, in which a portion of a component attached to a cover window does not detach from the cover window when the display apparatus is folded, and a method of manufacturing the display apparatus. Embodiments set forth herein are examples, and embodiments of the disclosure are not limited thereto.

According to one or more embodiments, a display apparatus includes a display panel that includes display elements, and a cover window disposed above the display panel and that includes a window, a first protective layer, and a second protective layer. The window includes a first non-folded area, a second non-folded area, and a foldable area located between the first non-folded area and the second non-folded area, a plurality of trenches are formed in the foldable area. Depths of a trench formed adjacent to the first non-folded area and a trench formed adjacent to the second non-folded area are greater than a depth of a trench formed in a central area of the foldable area.

The window may include a first window surface in a direction of the display panel and a second window surface in a direction opposite to the direction of the display panel. The plurality of trenches may include first trenches formed in the first window surface and second trenches formed in the second window surface, and in a plan view, the first trenches and the second trenches may be alternately arranged.

The foldable area may include a first foldable area adjacent to the first non-folded area, a second foldable area adjacent to the second non-folded area, and a third foldable area located between the first foldable area and the second foldable area. The first trenches may include a 1st-1 trench formed in the first foldable area, a 2nd-1 trench formed in the second foldable area, and a 3rd-1 trench formed in the third foldable area. A depth of the 1st-1 trench and a depth of the 2nd-1 trench may be each greater than a depth of the 3rd-1 trench.

The first protective layer may be disposed below the foldable area, and a portion of the first protective layer may have a slope.

A portion of the first protective layer disposed below the first foldable area may have a 1st-1 slope, and a portion of the first protective layer disposed below the second foldable area may have a 2nd-1 slope.

The 1st-1 trench may include a 1st-1-1 trench, a 1st-1-2 trench, and a 1st-1-3 trench. The 1st-1-1 trench may be formed in a portion of the first foldable area adjacent to the first non-folded area, the 1st-1-2 trench may be formed in a portion of the first foldable area adjacent to the second foldable area, and the 1st-1-3 trench may be formed in a portion of the first foldable area located between the portion of the first foldable area where the 1st-1-1 trench is formed and the portion of the first foldable area where the 1st-1-2 trench is formed. A depth of the 1st-1-3 trench may be greater than a depth of the 1st-1-2 trench, and a depth of the 1st-1-1 trench may be greater than the depth of the 1st-1-3 trench.

The 2nd-1 trench may include a 2nd-1-1 trench, a 2nd-1-2 trench, and a 2nd-1-3 trench. The 2nd-1-1 trench may be formed in a portion of the second foldable area adjacent to the second non-folded area, the 2nd-1-2 trench may be formed in a portion of the second foldable area adjacent to the third foldable area, and the 2nd-1-3 trench may be formed in a portion of the second foldable area between the portion of the second foldable area where the 2nd-1-1 trench is formed and the portion of the second foldable area where the 2nd-1-2 trench is formed. A depth of the 2nd-1-3 trench may be greater than a depth of the 2nd-1-2 trench, and a depth of the 2nd-1-1 trench may be greater than the depth of the 2nd-1-3 trench.

The display apparatus may further include a lower adhesive layer disposed between the display panel and the cover window.

The second trenches may include a 1st-2 trench formed in the first foldable area, a 2nd-2 trench formed in the second foldable area, and a 3rd-2 trench formed in the third foldable area. A depth of the 1st-2 trench and a depth of the 2nd-2 trench may be each greater than a depth of the 3rd-2 trench.

The second protective layer may be disposed on the foldable area, and a portion of the second protective layer may have a slope.

A portion of the second protective layer disposed above the first foldable area may have a 1st-2 slope, and a portion of the second protective layer disposed above the second foldable area may have a 2nd-2 slope.

The 1st-2 trench may include a 1st-2-1 trench, a 1st-2-2 trench, and a 1st-2-3 trench. The 1st-2-1 trench may be formed in a portion of the first foldable area adjacent to the first non-folded area, the 1st-2-2 trench may be formed in a portion of the first foldable area adjacent to the third foldable area, and the 1st-2-3 trench may be formed in a portion of the first foldable area located between the portion of the first foldable area where the 1st-2-1 trench is formed and the portion of the first foldable area where the 1st-2-2 trench is formed. A depth of the 1st-2-3 trench may be greater than a depth of the 1st-2-2 trench, and a depth of the 1st-2-1 trench may be greater than the depth of the 1st-2-3 trench.

The 2nd-2 trench may include a 2nd-2-1 trench, a 2nd-2-2 trench, and a 2nd-2-3 trench. The 2nd-2-1 trench may be formed in a portion of the second foldable area adjacent to the second non-folded area, the 2nd-2-2 trench may be formed in a portion of the second foldable area adjacent to the third foldable area, and the 2nd-2-3 trench may be formed in a portion of the second foldable area located between the portion of the second foldable area where the 2nd-2-1 trench is formed and the portion of the second foldable area where the 2nd-2-2 trench is formed. A depth of the 2nd-2-3 trench may be greater than a depth of the 2nd-2-2 trench, and a depth of the 2nd-2-1 trench may be greater than the depth of the 2nd-2-3 trench.

The display apparatus may further include a protective film disposed above the cover window, and an upper adhesive layer disposed between the cover window and the protective film.

According to one or more embodiments, a method of manufacturing a display apparatus includes providing a window that includes a first non-folded area, a second non-folded area, and a foldable area located between the first non-folded area and the second non-folded area, wherein a plurality of trenches are formed in the foldable area, attaching a release film to the window by using a release film adhesive layer, filling a space with a protective layer composition, where the space is surrounded by the release film adhesive layer, the release film, and the portion of the window in which the plurality of trenches are formed, irradiating ultraviolet light onto the protective layer composition, and removing the release film adhesive layer and the release film from the window. Depths of a trench formed adjacent to the first non-folded area and a trench formed adjacent to the second non-folded area are greater than a depth of a trench formed in a central area of the foldable area.

The window may include a first window surface and a second window surface opposite to the first window surface. The plurality of trenches may include first trenches formed in the first window surface and second trenches formed in the second window surface, and in a plan view, the first trenches and the second trenches may be alternately arranged.

The foldable area may include a first foldable area adjacent to the first non-folded area, a second foldable area adjacent to the second non-folded area, and a third foldable area located between the first foldable area and the second foldable area. The first trenches may include a 1st-1 trench formed in the first foldable area, a 2nd-1 trench formed in the second foldable area, and a 3rd-1 trench formed in the third foldable area. A depth of the 1st-1 trench and a depth of the 2nd-1 trench may each be greater than a depth of the 3rd-1 trench.

The second trenches may include a 1st-2 trench formed in the first foldable area, a 2nd-2 trench formed in the second foldable area, and a 3rd-2 trench formed in the third foldable area. A depth of the 1st-2 trench and a depth of the 2nd-2 trench may each be greater than a depth of the 3rd-2 trench.

Attaching the release film may include attaching a first release film to the window by using a first release film adhesive layer disposed on the first window surface of the first non-folded area and the second non-folded area, and attaching a second release film to the window by using a second release film adhesive layer disposed on the second window surface of the first non-folded area and the second non-folded area.

Filling the space with the protective layer composition may include filling a first space with a first protective layer composition, where the first space is surrounded by the first release film adhesive layer, the first release film, and the portion of the window in which the first trenches are formed, and filling a second space with a second protective layer composition, wherein the second space is surrounded by the second release film adhesive layer, the second release film, and the portion of the window in which the second trenches are formed.

Irradiating the ultraviolet light may include forming a first protective layer by irradiating ultraviolet light onto the first protective layer composition, and forming a second protective layer by irradiating ultraviolet light onto the second protective layer composition.

A portion of the first protective layer disposed below a portion of the foldable area adjacent to the first non-folded area may have a first slope, and a portion of the first protective layer disposed below a portion of the foldable area adjacent to the second non-folded area may have a second slope.

A portion of the second protective layer disposed above a portion of the foldable area adjacent to the first non-folded area may have a first slope, and a portion of the second protective layer disposed above a portion of the foldable area adjacent to the second non-folded area may have a second slope.

According to one or more embodiments, a display apparatus comprises a display panel that includes display elements; and a cover window disposed above the display panel and that includes a window. The window includes a first window surface in a direction of the display panel and a second window surface in a direction opposite to the direction of the display panel, a first non-folded area, a second non-folded area, and a foldable area between the first non-folded area and the second non-folded area. A plurality of trenches are formed in one of the first window surface or the second window surface, and depths of a trench formed adjacent to the first non-folded area and a trench formed adjacent to the second non-folded area are greater than a depth of a trench formed in a central area of the foldable area.

The cover window may further include a first protective layer and a second protective layer. The first protective layer is disposed below the foldable area, the second protective layer is disposed on the foldable area, and a portion of one of the first or second protective layers that corresponds to where plurality of trenches are formed may have a slope.

These and/or other aspects will become apparent and more readily appreciated from the following description of the embodiments, the accompanying drawings, and claims.

### BRIEF DESCRIPTION OF THE DRAWINGS

FIG. 1 is a schematic perspective view of a display apparatus according to an embodiment.

FIG. 2 is a schematic cross-sectional view of a display apparatus according to an embodiment.

FIG. 3 is a schematic cross-sectional view of a display apparatus of FIG. 1, taken along line I-I′ of FIG. 1.

FIG. 4 is a schematic plan view of a portion of a display apparatus according to an embodiment.

FIG. 5 is a schematic enlarged cross-sectional view of an area A of a display apparatus of FIG. 3.

FIG. 6 is a schematic enlarged cross-sectional view of area A of a display apparatus of FIG. 3.

FIG. 7 is a schematic cross-sectional view of a display apparatus according to a comparative example.

FIG. 8 illustrates deformation of a lower adhesive layer when a display apparatus according to a comparative example is folded.

FIG. 9 illustrates deformation of a lower adhesive layer when a display apparatus according to an embodiment is folded.

FIG. 10 is a schematic cross-sectional view of a portion of a display apparatus according to an embodiment.

FIG. 11 is a schematic cross-sectional view of a portion of a display apparatus according to an embodiment.

FIG. 12 is a schematic cross-sectional view of a portion of a display panel in a display apparatus according to an embodiment.

FIGS. 13 to 18 are schematic cross-sectional views that illustrate a process of manufacturing a display apparatus of FIG. 3.

FIG. 19 is a schematic plan view of a portion of a display apparatus according to an embodiment.

FIG. 20 is a schematic plan view of a portion of a display apparatus according to an embodiment.

### DETAILED DESCRIPTION

Reference will now be made in detail to embodiments, examples of which are illustrated in the accompanying drawings, wherein like reference numerals may refer to like elements throughout. In this regard, the present embodiments may have different forms and should not be construed as being limited to the descriptions set forth herein. Accordingly, the embodiments are merely described below, by referring to the figures, to explain aspects of the present description.

In the present specification, it will be understood that when a layer, region, or component is referred to as being “formed on” another layer, region, or component, it can be directly or indirectly formed on the other layer, region, or component.

In the present specification, when layers, regions, or components are connected to each other, the layers, the regions, or the components may be directly connected to each other, or another layer, another region, or another component may be interposed between the layers, the regions, or the components and thus the layers, the regions, or the components may be indirectly connected to each other.

In the present specification, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

In the present specification, “in a plan view” means when the subject part is viewed from above. That is, in the present specification, “in a plan view” may mean “when viewed from a direction perpendicular to the window W”.

Hereinafter, exemplary embodiments will be described in detail with reference to the accompanying drawings, and in the description with reference to the drawings, the same or corresponding constituents may be indicated by the same reference numerals and redundant descriptions thereof are omitted

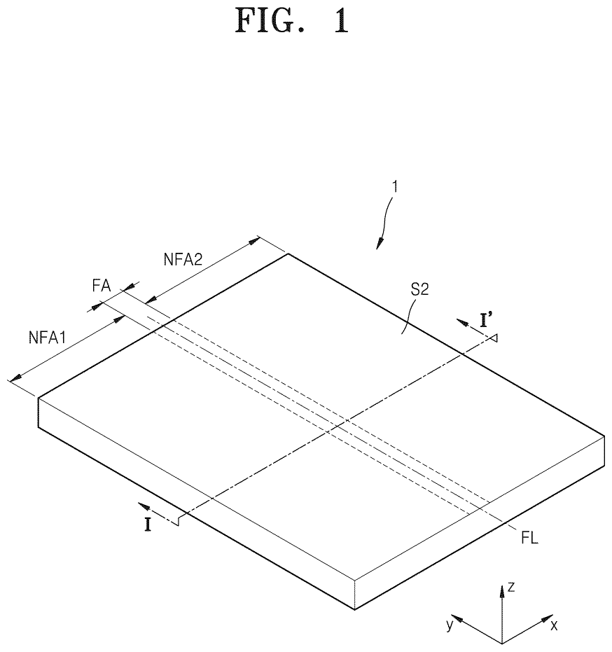

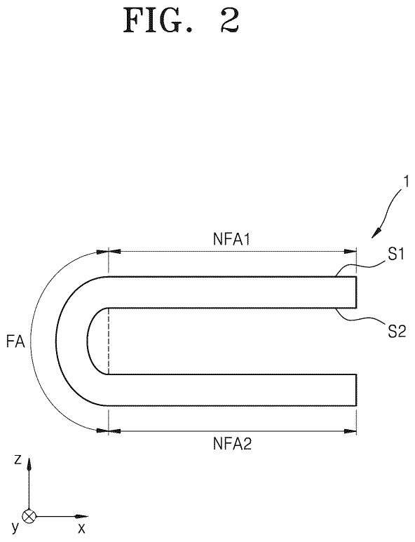

FIG. 1 is a schematic perspective view of a display apparatus 1 according to an embodiment, and FIG. 2 is a schematic cross-sectional view of a display apparatus 1 according to an embodiment. For example, FIG. 1 is a perspective view of the display apparatus 1 in an unfolded state, and FIG. 2 is a cross-sectional view of the display apparatus 1 in a folded state.

The display apparatus 1 may have a polygonal shape such as a rectangle. For example, the display apparatus 1 has a rectangular shape in which a horizontal length thereof is greater than a vertical length, a rectangular shape in which a horizontal length thereof is less than a vertical length, or a square shape. In some embodiments, the display apparatus 1 has various other shapes such as an elliptical shape or a circular shape. Although FIG. 1 shows that the display apparatus 1 has a rectangular shape in which a horizontal length is greater than a vertical length, embodiments of the disclosure are not necessarily limited thereto.

The display apparatus 1 has a first surface S1 and a second surface S2 opposite to the first surface S1. In an embodiment, the first surface S1 is a lower surface (in a −z direction) of the display apparatus 1, and the second surface S2 is an upper surface (in a +z direction) of the display apparatus 1. The display apparatus 1 displays an image on the second surface S2. For example, the second surface S2 includes a display surface. In some embodiments, the display apparatus 1 also displays an image on the first surface S1.

The display apparatus 1 can be folded. For example, at least a portion of the display apparatus 1 is flexible, and when the flexible portion is bent, the display apparatus 1 can be folded. Accordingly, the display apparatus 1 includes a foldable area and a non-folded area on at least one side of the foldable area. In the present specification, “non-folded” means not folded, which includes not only a case of being inflexible and hard to fold, but also a case of being flexible but not being folded. The display apparatus 1 can display images in not only the non-folded area but also the foldable area.

As shown in FIG. 1, the display apparatus 1 includes a first non-folded area NFA1, a second non-folded area NFA2, and a foldable area FA. The first non-folded area NFA1 and the second non-folded area NFA2 are non-folded areas, and the foldable area FA is a foldable flexible region.

The foldable area FA extends in a direction that crosses a virtual straight line that connects the first non-folded area NFA1 and the second non-folded area NFA2 to each other. For example, when the display apparatus 1 is in an unfolded state, the first non-folded area NFA1 and the second non-folded area NFA2 are spaced apart from each other in a first direction, such as an x-axis direction. The foldable area FA is located between the first non-folded area NFA1 and the second non-folded area NFA2. For example, the first non-folded area NFA1 is adjacent to one side of the foldable area FA, and the second non-folded area NFA2 is adjacent to the other side of the foldable area FA. When the display apparatus 1 is in an unfolded state, the foldable area FA extends in a second direction, such as a y-axis direction, that crosses the first direction, such as the x-axis direction.

A folding line FL may be defined in the foldable area FA that extends in the second direction, such as the y-axis direction, which is the extension direction of the foldable area FA. Accordingly, the display apparatus 1 can be folded in the foldable area FA. The foldable area FA and the folding line FL of the foldable area FA overlap a region in which images of the display apparatus 1 are displayed. When the display apparatus 1 is folded, a portion in which images are displayed is folded.

For convenience of description, although FIG. 1 shows that the first non-folded area NFA1 and the second non-folded area NFA2 have the same or similar area and the display apparatus 1 includes one foldable area FA, embodiments of the disclosure are not necessarily limited thereto. For example, in other embodiments, the first non-folded area NFA1 and the second non-folded area NFA2 have different areas. In other embodiments, the display apparatus 1 includes a plurality of foldable areas FA. For example, the plurality of non-folded areas are spaced apart from each other, and each of the plurality of foldable areas FA is arranged between the non-folded areas. Each foldable area FA can be folded with respect to a folding line FL, and a plurality of folding line FL are provided.

Although FIG. 1 shows that the folding line FL passes through the center of the foldable area FA, and the foldable area FA is symmetric with respect to the folding line FL, embodiments of the disclosure are not necessarily limited thereto. In some embodiments, the folding line FL is asymmetrically located in the foldable area FA.

As shown in FIG. 2, the display apparatus 1 can be folded such that the second surface S2 of the first non-folded area NFA1 faces the second surface S2 of the second non-folded area NFA2. For example, when the foldable area FA of the display apparatus 1 is bent, the second surface S2 of the first non-folded area NFA1 and the second surface S2 of the second non-folded area NFA2 face each other. Even when the display apparatus 1 is folded, the foldable area FA extends in a direction that crosses a virtual straight line that connects the first non-folded area NFA1 and the second non-folded area NFA2 to each other. For example, when the display apparatus 1 is folded, the foldable area FA extends in the second direction, such as the y-axis direction, that crosses a virtual straight line, such as a straight line parallel to the z-axis direction, that connects the first non-folded area NFA1 and the second non-folded area NFA2 to each other. The foldable area FA can be folded and then unfolded. For example, the display apparatus 1 is a foldable display apparatus.

In the present specification, the term “folding” means a shape is not fixed but changes from the original shape to a different shape and includes being folded, curved, or bent along at least one specific line, such as the folding line FL. Accordingly, although FIG. 2 shows the state in which the second surface S2 of the first non-folded area NFA1 and the second surface S2 of the second non-folded area NFA2 are folded to be parallel to each other and to face each other, embodiments of the disclosure are not necessarily limited thereto. For example, the second surface S2 of the first non-folded area NFA1 and the second surface S2 of the second non-folded area NFA2 can be folded to form a preset angle, such as an acute angle, a right angle, or an obtuse angle, with the foldable area FA therebetween.

In addition, although FIG. 2 shows that the display apparatus 1 is in-folded so that one portion of the second surface S2 and another portion of the second surface S2 face each other, embodiments of the disclosure are not necessarily limited thereto. For example, the display apparatus 1 may be out-folded so that one portion of the first surface S1 and another portion of the first surface S1 face each other. For example, the display apparatus 1 is in an in-folding state when portions of the display surface are folded to face each other, or is in an out-folding state when a display surface is folded to be externally exposed. Hereinafter, for convenience of explanation, the description will focus on a case where the display apparatus 1 is in an in-folding state.

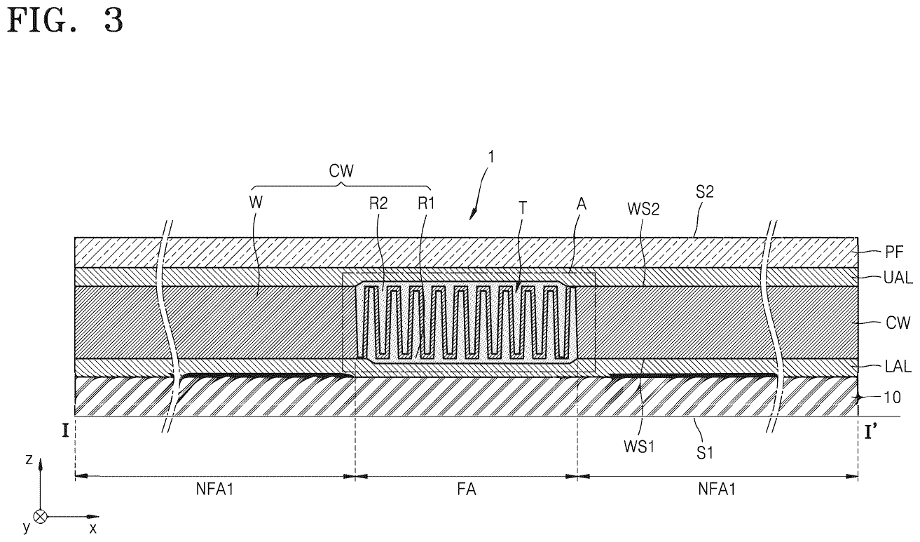

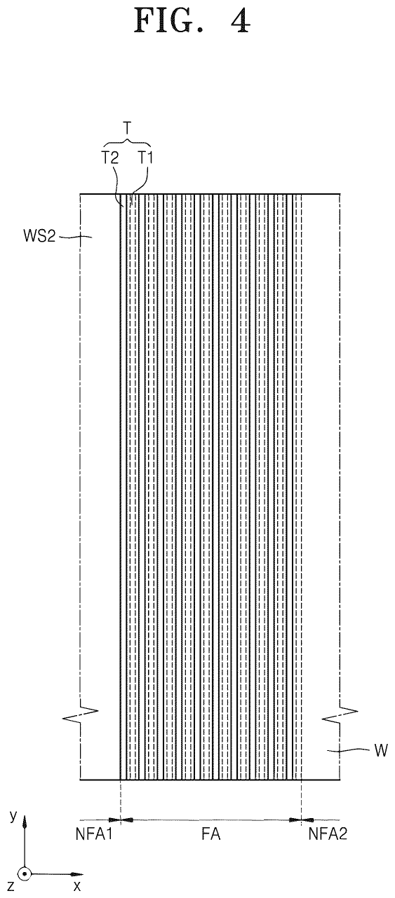

FIG. 3 is a schematic cross-sectional view of a display apparatus 1 of FIG. 1, taken along line I-I′ of FIG. 1. FIG. 4 is a schematic plan view of a portion of a display apparatus 1 according to an embodiment. FIG. 4 shows a plan view on a window W for convenience. FIG. 4 shows second trenches T2 together for convenience of illustration.

As shown in FIG. 3, in an embodiment, the display apparatus 1 includes a display panel 10, a cover window CW, and a protective film PF. The display panel 10 displays images. For example, the display panel 10 includes a plurality of display elements, and the plurality of display elements emit light. Accordingly, the display panel 10 displays images through light emitted from the plurality of display elements. In an embodiment, each of the display elements is an organic light-emitting diode that includes an organic emission layer. In an embodiment, the display element is a light-emitting diode. The light-emitting diode is microscalar or nanoscalar in size. For example, the light-emitting diode is a micro light-emitting diode. In some embodiments, the light-emitting diode is a nanorod light-emitting diode. The nanorod light-emitting diode includes gallium nitride (GaN). In an embodiment, a color conversion layer is disposed on the nanorod light-emitting diode. The color conversion layer includes quantum dots. In an embodiment, the display element is a quantum-dot light-emitting diode that includes a quantum-dot emission layer. In an embodiment, the display element is an inorganic light-emitting diode that includes an inorganic semiconductor. Detailed descriptions of the components included in the display panel 10 are provided below.

The cover window CW is disposed above the display panel 10. The cover window CW covers an upper surface (in the +z direction) of the display panel 10. The cover window CW protects the upper surface (in the +z direction) of the display panel 10. The cover window CW has a high transmittance that transmits light emitted from the display panel 10 and has a small thickness that reduces the weight of the display apparatus 1. In addition, the cover window CW has high strength and hardness that protects the display panel 10 from external shock. A lower adhesive layer LAL is disposed between the display panel 10 and the cover window CW. The cover window CW is attached to the display panel 10 by the lower adhesive layer LAL. The lower adhesive layer LAL includes an adhesive member, such as an optical clear adhesive (OCA) or a pressure sensitive adhesive (PSA).

The cover window CW includes a window W, a first protective layer R1, and a second protective layer R2. The window W is disposed in each of the first non-folded area NFA1, the second non-folded area NFA2, and the foldable area FA, and the first protective layer R1 and the second protective layer R2 are disposed in the foldable area FA. The window W is flexible. The window W protects the display panel 10 by easily bending in response to external forces without causing cracks, etc. The window W may include glass or plastic. In an embodiment, the window W includes ultra-thin glass (UTG) that has been strengthened by chemical strengthening or thermal strengthening. In an embodiment, the window W includes a polymer resin. As described above, the display apparatus 1 includes a first non-folded area NFA1, a second non-folded area NFA2, and a foldable area FA. Because the display apparatus 1 includes the cover window CW and the cover window CW includes the window W, the window W includes the first non-folded area NFA1 and the second non-folded area NFA2, and the foldable area FA as described above. Hereinafter, for convenience, the window W will be described as including the first non-folded area NFA1, the second non-folded area NFA2, and the foldable area FA.

The window W includes a first window surface WS1 and a second window surface WS2. The first window surface WS1 corresponds to the first surface S1 of the display apparatus 1, and the second window surface WS2 corresponds to the second surface S2 of the display apparatus 1. For example, the first window surface WS1 of the window W faces the same direction, such as the −z direction, as the first surface S1 of the display apparatus 1, and the second window surface WS2 of the window W faces the same direction, such as the +z direction, as the second surface S2 of the display apparatus 1. For example, the second window surface WS2 is opposite to the first window surface WS1. For example, the first window surface WS1 faces the direction of the display panel 10 and the second window surface WS2 faces a direction opposite to the display panel 10.

For example, when the window W is in an unfolded state, the first non-folded area NFA1 and the second non-folded area NFA2 are spaced apart from each other in the first direction, such as the x-axis direction, that crosses the second direction, such as the y-axis direction. The foldable area FA is located between the first non-folded area NFA1 and the second non-folded area NFA2 and extends in the second direction, such as the y-axis direction, that crosses a virtual straight line that connects the first non-folded area NFA1 to the second non-folded area NFA2.

The folding line FL is defined in the foldable area FA and extends in the second direction, such as the y-axis direction, which is the extension direction of the foldable area FA. Accordingly, the window W can be folded in the foldable area FA. The window W can be folded so that the second window surface WS2 of the first non-folded area NFA1 and the second window surface WS2 of the second non-folded area NFA2 face each other based on the folding line FL. For example, as the foldable area FA of the window W is bent, the second window surface WS2 of the first non-folded area NFA1 and the second window surface of the second non-folded area NFA2 come together to face each other.

A plurality of trenches T are formed in the foldable area FA of the window W. For example, the window W includes a plurality of trenches T, and the plurality of trenches T are formed in the foldable area FA. The number of trenches T formed in the foldable area FA of the window W can change in various ways. The plurality of trenches T are alternately located on both sides of the window W. For example, part of the plurality of trenches T are formed in the first window surface WS1, and another part of the plurality of trenches T are formed in the second window surface WS2. For example, as shown in FIG. 4, the plurality of trenches T include first trenches T1 and second trenches T2. The first trenches T1 are formed in the first window surface WS1, and the second trenches T2 are formed in the second window surface WS2.

Each of the trenches T is an area where a portion of the window W has been removed. For example, forming a trench in one surface of a window includes removing a portion of the window from one surface of the window in a thickness direction of the window, so that only a portion of the window adjacent to the other surface of the window remains. For example, each of the first trenches T1 is formed where a portion of the window W is removed from the first window surface WS1 in a third direction, such as a z-axis direction. A portion of the window W adjacent to the second window surface WS2 that corresponds to the first trench T1 remains. Each of the second trenches T2 is formed where a portion of the window W is removed from the second window surface WS2 in the third direction, such as the z-axis direction. A portion of the window W adjacent to the first window surface WS1 that corresponds to the second trench T2 remains.

In a plan view, the trenches T formed in the first window surface WS1 and the trenches T formed in the second window surface WS2 are alternately arranged. For example, as shown in FIG. 4, the first trenches T1 and the second trenches T2 are alternately arranged in a plan view. When the plurality of trenches T are formed in the foldable area FA of the window W, the folding operation of the window W becomes easier.

Each of the first and second trenches T1 and T2 extends in the second direction, such as the y-axis direction, that crosses the first direction, such as the x-axis direction. A longitudinal direction of each of the first and second trenches T1 and T2 is the second direction, such as the y-axis direction. In an embodiment, as shown in FIG. 4, the length of each of the first and second trenches T1 and T2 in the second direction, such as the y-axis direction, is equal to the width of the window W in the second direction, such as the y-axis direction. In an embodiment, the length of each of the first and second trenches T1 and T2 in the second direction, such as the y-axis direction, differs from the width of the window W in the second direction, such as the y-axis direction. In an embodiment, the depth of each of the first and second trenches T1 and T2 in the third direction, such as the z-axis direction, is less than the thickness of the window W in the third direction, such as the z-axis direction. A depth direction of each of the first and second trenches T1 and T2 is the third direction, such as the z-axis direction. A detailed description of the depth of each of the first and second trenches T1 and T2 is provided below.

The first protective layer R1 is disposed in the foldable area FA. For example, the first protective layer R1 is disposed on the first window surface WS1 in the foldable area FA. In addition, the first protective layer R1 fills in the first trenches T1 formed in the first window surface WS1. The first protective layer R1 includes an optically transparent material that has low physical strength and hardness. The first protective layer R1 includes a flexible material. Accordingly, the first protective layer R1 can be tensioned or compressed by an external force. For example, the first protective layer R1 includes at least one of a silicone-based resin, an optical clear resin (OCR), or an OCA. The modulus of the first protective layer R1 is less than the modulus of the window W. The first protective layer R1 has a refractive index that is substantially the same as that of the window W.

The second protective layer R2 is disposed in the foldable area FA. For example, the second protective layer R2 is disposed on the second window surface WS2 in the foldable area FA. In addition, the second protective layer R2 fills in the second trenches T2 formed in the second window surface WS2. The second protective layer R2 includes a material that is the same as or substantially similar to that of the first protective layer R1. For example, the second protective layer R2 includes an optically transparent material that has low physical strength and hardness. The second protective layer R2 includes a flexible material. Accordingly, the second protective layer R2 can be tensioned or compressed by an external force. For example, the second protective layer R2 includes at least one of a silicone-based resin, an OCR, or an OCA. The modulus of the second protective layer R2 is less than the modulus of the window W. The second protective layer R2 has a refractive index that is substantially the same as that of the window W.

The protective film PF is disposed above the cover window CW. The protective film PF protects the cover window CW and prevents or reduces scratches on the upper surface (in the +z direction) of the cover window CW. In an embodiment, the protective film PF includes a polymer resin. In an embodiment, the protective film PF includes an inorganic material. An upper adhesive layer UAL is disposed between the cover window CW and the protective film PF. The protective film PF is attached to the cover window CW by the upper adhesive layer UAL. The upper adhesive layer UAL includes an adhesive member, such as an OCA or a PSA.

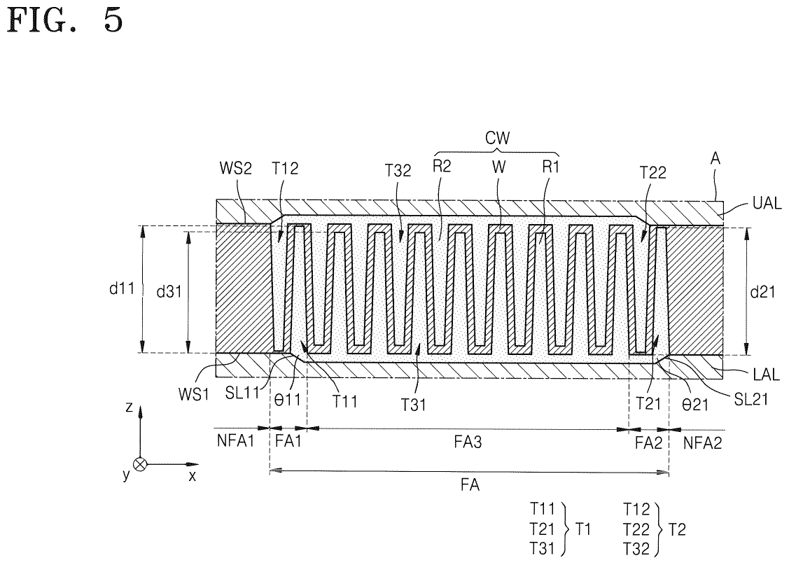

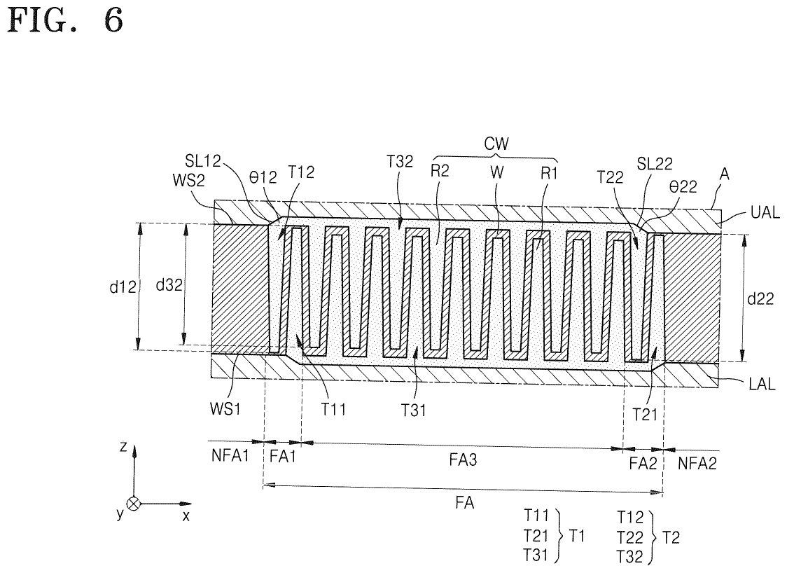

FIG. 5 is a schematic enlarged cross-sectional view of an area A of the display apparatus 1 of FIG. 3. FIG. 6 is a schematic enlarged cross-sectional view of the area A of the display apparatus 1 of FIG. 3. As shown in FIGS. 5 and 6, the depth of each trench T can vary depending on its location in the foldable area FA.

For example, as shown in FIG. 5, the foldable area FA includes a first foldable area FA1, a second foldable area FA2, and a third foldable area FA3. The first foldable area FA1 is adjacent to the first non-folded area NFA1, and the second foldable area FA2 is adjacent to the second non-folded area NFA2. The third foldable area FA3 is between the first foldable area FA1 and the second foldable area FA2. For example, the third foldable area FA3 includes a central area of the foldable area FA. The central area of the foldable area FA includes the center of the foldable area FA.

As described above, the first non-folded area NFA1 and the second non-folded area NFA2 are spaced apart from each other in the first direction, such as the x-axis direction, the first non-folded area NFA1 is adjacent to one side of the foldable area FA and the second non-folded area NFA2 is adjacent to the other side of the foldable area FA. For example, the distance in the first direction, such as the x-axis direction, between one end of the foldable area FA in contact with the first non-folded area NFA1 and the center of the foldable area FA is equal to the distance in the first direction, such as the x-axis direction, between the other end of the foldable area FA in contact with the second non-folded area NFA2 and the center of the foldable area FA. For example, the center of the foldable area FA is a portion of the foldable area FA in which the distance from the first non-folded area NFA1 in the first direction, such as the x-axis direction, is equal to the distance from the second non-folded area NFA2 in the first direction, such as the x-axis direction. For example, the center of the foldable area FA is a portion of the foldable area FA located furthest in the first direction, such as the x-axis direction, from the first non-folded area NFA1 and the second non-folded area NFA2.

As described above, the plurality of trenches T includes first trenches T1 and second trenches T2. The first trenches T1 include a 1st-1 trench T11, a 2nd-1 trench T21, and a 3rd-1 trench T31. The 1st-1 trench T11 is formed in the first foldable area FA1, the 2nd-1 trench T21 is formed in the second foldable area FA2, and the 3rd-1 trench T31 is formed in the third foldable area FA3. For example, the 1st-1 trench T11 is formed in a first window surface WS1 of the first foldable area FA1, the 2nd-1 trench T21 is formed in a first window surface WS1 of the second foldable area FA2, and the 3rd-1 trench T31 is formed in a first window surface WS1 of the third foldable area FA3.

Similarly, the second trenches T2 include a 1st-2 trench T12, a 2nd-2 trench T22, and a 3rd-2 trench T32. The 1st-2 trench T12 is formed in the first foldable area FA1, the 2nd-2 trench T22 is formed in the second foldable area FA2, and the 3rd-2 trench T32 is formed in the third foldable area FA3. For example, the 1st-2 trench T12 is formed in a second window surface WS2 of the first foldable area FA1, the 2nd-2 trench T22 is formed in a second window surface WS2 of the second foldable area FA2, and the 3rd-2 trench T32 is formed in a second window surface WS2 of the third foldable area FA3.

As shown in FIG. 5, the depth of a trench T adjacent to the first non-folded area NFA1 is greater than the depth of a trench in the central area of the foldable area FA. For example, the depth of a first trench T1 in the first foldable area FA1 is greater than the depth of a first trench T1 in the third foldable area FA3. For example, the 1st-1 trench T11 has a 1st-1 depth d11, and the 3rd-1 trench T31 has a 3rd-1 depth d31. The 1st-1 depth d11 is greater than the 3rd-1 depth d31.

The depth of a trench T adjacent to the second non-folded area NFA2 is greater than the depth of the trench T formed in the center area of the foldable area FA. For example, the depth of a first trench T1 in the second foldable area FA2 is greater than the depth of the first trench T1 in the third foldable area FA3. For example, the 2nd-1 trench T21 has a 2nd-1 depth d21, and the 2nd-1 depth d21 is greater than a 3rd-1 depth d31.

In the present specification, the depth of the first trench T1 refers to the shortest distance between the bottom surface of the first trench T1 and a virtual extension surface parallel to the first window surface WS1. For example, the 1st-1 depth d11 refers to the shortest distance between the bottom surface of the 1st-1 trench T11 and the virtual extension surface parallel to the first window surface WS1, the 2nd-1 depth d21 refers to the shortest distance between the bottom surface of the 2nd-1 trench T21 and the virtual extension surface parallel to the first window surface WS1, and the 3rd-1 depth d31 refers to the shortest distance between the bottom surface of the 3rd-1 trench T31 and the virtual extension surface parallel to the first window surface WS1.

However, in the present specification, the depth of the first trench T1 also refers to the shortest distance between the first window surface WS1 and the bottom surface of the first trench T1 in a thickness direction, such as the z-axis direction, of the window W. For example, the 1st-1 depth d11 refers to the shortest distance between the first window surface WS1 and the bottom surface of the 1st-1 trench T11 in the thickness direction, such as the z-axis direction, of the window W, the 2nd-1 depth d21 refers to the shortest distance between the first window surface WS1 and the bottom surface of the 2nd-1 trench T21 in the thickness direction, such as the z-axis direction, of the window W, and the 3rd-1 depth d31 refers to the shortest distance between the first window surface WS1 and the bottom surface of the 3rd-1 trench T31 in the thickness direction, such as the z-axis direction, of the window W.

Similarly, as shown in FIG. 6, the depth of a second trench T2 formed in the first foldable area FA1 is greater than the depth of a second trench T2 formed in the third foldable area FA3. For example, the 1st-2 trench T12 has a 1st-2 depth d12, and the 3rd-2 trench T32 has a 3rd-2 depth d32. The 1st-2 depth d12 is greater than the 3rd-2 depth d32. The depth of a second trench T2 formed in the second foldable area FA2 is greater than the depth of a second trench T2 formed in the third foldable area FA3. For example, the 2nd-2 trench T22 has a 2nd-2 depth d22, and the 2nd-2 depth d22 is greater than a 3rd-2 depth d32.

In the present specification, the depth of the second trench T2 refers to the shortest distance between the bottom surface of the second trench T2 and a virtual extension surface parallel to the second window surface WS2. For example, the 1st-2 depth d12 refers to the shortest distance between the bottom surface of the 1st-2 trench T12 and the virtual extension surface parallel to the second window surface WS2, the 2nd-2 depth d22 refers to the shortest distance between the bottom surface of the 2nd-2 trench T22 and the virtual extension surface parallel to the second window surface WS2, and the 3rd-2 depth d32 refers to the shortest distance between the bottom surface of the 3rd-2 trench T32 and the virtual extension surface parallel to the second window surface WS2.

However, in the present specification, the depth of the second trench T2 also refers to the shortest distance between the second window surface WS2 and the bottom surface of the second trench T2 in the thickness direction, such as the z-axis direction, of the window W. For example, the 1st-2 depth d12 refers to the shortest distance between the second window surface WS2 and the bottom surface of the 1st-2 trench T12 in the thickness direction, such as the z-axis direction, of the window W, the 2nd-2 depth d22 refers to the shortest distance between the second window surface WS2 and the bottom surface of the 2nd-2 trench T22 in the thickness direction, such as the z-axis direction, of the window W, and the 3rd-2 depth d32 refers to the shortest distance between the second window surface WS2 and the bottom surface of the 3rd-2 trench T32 in the thickness direction, such as the z-axis direction, of the window W.

As described above, the first protective layer R1 is disposed on the first window surface WS1 of the foldable area FA and fills the first trenches T1 formed in the first window surface WS1. A portion of the first protective layer R1 has a slope, such as an inclined surface. For example, a portion of the first protective layer R1 adjacent to the first non-folded area NFA1 has a slope, and a portion of the first protective layer R1 adjacent to the second non-folded area NFA2 has a slope. For example, a portion of the first protective layer R1 disposed in the first foldable area FA1 has a 1st-1 slope SL11, and a portion of the first protective layer R1 disposed in the second foldable area FA2 has a 2nd-1 slope SL21.

The 1st-1 slope SL11 is inclined with respect to a virtual extension surface parallel to the first window surface WS1 of the first non-folded area NFA1 of the window W, and the 1st-2 slope SL12 is inclined with respect to a virtual extension surface parallel to the first window surface WS1 of the second non-folded area NFA2 of the window W. For example, the angle at which the 1st-1 slope SL11 is inclined with respect to the virtual extension surface parallel to the first window surface WS1 of the first non-folded area NFA1 is a 1st-1 angle θ11. The 1st-1 angle θ11 is greater than 0° and less than 90°. The angle at which the 2nd-1 slope SL21 is inclined with respect to the virtual extension surface parallel to the first window surface WS1 of the second non-folded area NFA2 is a 2nd-1 angle θ21. The 2nd-1 angle θ21 is greater than 0° and less than 90°. For example, each of the 1st-1 angle θ11 and the 2nd-1 angle θ21 is an acute angle. For example, the first protective layer R1 has a forward tapered slope.

As described above, the second protective layer R2 is disposed on the second window surface WS2 of the foldable area FA and fills the second trenches T2 formed in the second window surface WS2. Similarly, as shown in FIG. 6, a portion of the second protective layer R2 has a slope. For example, a portion of the second protective layer R2 adjacent to the first non-folded area NFA1 has a slope, and a portion of the second protective layer R2 adjacent to the second non-folded area NFA2 has a slope. For example, a portion of the second protective layer R2 disposed in the first foldable area FA1 has a 1st-2 slope SL12, and a portion of the second protective layer R2 disposed in the second foldable area FA2 has a 2nd-2 slope SL22.

The 1st-2 SL12 is inclined with respect to a virtual extension surface parallel to the second window surface WS2 of the first non-folded area NFA1 of the window W, and the 2nd-2 slope SL22 is inclined with respect to a virtual extension surface parallel to the second window surface WS2 of the second non-folded area NFA2 of the window W. For example, the angle at which the 1st-2 slope SL12 is inclined with respect to the virtual extension surface parallel to the second window surface WS2 of the first non-folded area NFA1 is a 1st-2 angle θ12. The 1st-2 angle θ12 is greater than 0° and less than 90°. The angle at which the 2nd-2 slope SL22 is inclined with respect to the virtual extension surface parallel to the second window surface WS2 of the second non-folded area NFA2 is a 2nd-2 angle θ22. The 2nd-2 angle θ22 is greater than 0° and less than 90°. For example, each of the 1st-2 angle θ12 and the 2nd-2 angle θ22 is an acute angle. For example, the second protective layer R2 has a forward tapered slope.

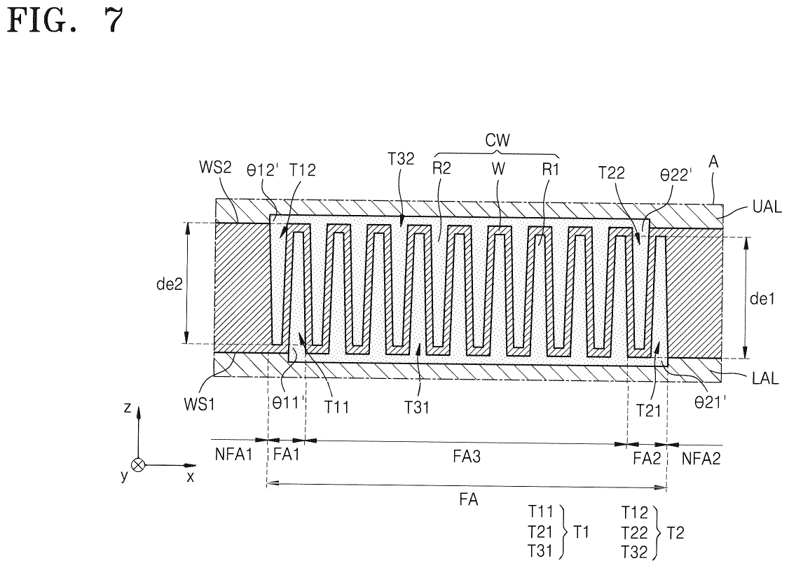

FIG. 7 is a schematic cross-sectional view of a display apparatus according to a comparative example. Because a display apparatus according to a comparative example is similar to the display apparatus 1 according to an embodiment, the following description will focus on differences from the display apparatus 1 according to an embodiment.

As shown in FIG. 7, for a display apparatus according to a comparative example, a plurality of trenches T are formed in the foldable area FA of the window W. The plurality of trenches T include first trenches T1 and second trenches T2. The first trenches T1 are formed in the first window surface WS1, and the second trenches T2 are formed in the second window surface WS2. The first protective layer R1 is disposed on the first window surface WS1 of the foldable area FA and fills the first trenches T1 formed in the first window surface WS1. The second protective layer R2 is disposed on the second window surface WS2 of the foldable area FA and fills the second trenches T2 formed in the second window surface WS2.

The first trenches T1 include a 1st-1 trench T11, a 2nd-1 trench T21, and a 3rd-1 trench T31. For example, the 1st-1 trench T11 is formed in a first window surface WS1 of the first foldable area FA1, the 2nd-1 trench T21 is formed in a first window surface WS1 of the second foldable area FA2, and the 3rd-1 trench T31 is formed in a first window surface WS1 of the third foldable area FA3. The second trenches T2 include a 1st-2 trench T12, a 2nd-2 trench T22, and a 3rd-2 trench T32. For example, the 1st-2 trench T12 is formed in a second window surface WS2 of the first foldable area FA1, the 2nd-2 trench T22 is formed in a second window surface WS2 of the second foldable area FA2, and the 3rd-2 trench T32 is formed in a second window surface WS2 of the third foldable area FA3.

However, for a display apparatus according to a comparative example, the depth of the 1st-1 trench T11 and the depth of the 2nd-1 trench T21 are each the same as or substantially similar to a depth de1 of the 3rd-1 trench T31. Similarly, the depth of the 1st-2 trench T12 and the depth of the 2nd-2 trench T22 are each the same as or substantially similar to a depth de2 of the 3rd-2 trench T32. For example, one end of the first protective layer R1 adjacent to the first non-folded area NFA1 forms a 1st-1 comparison angle θ11′ with the virtual extension surface parallel to the first window surface WS1 of the first non-folded area NFA1. The other end of the first protective layer R1 adjacent to the second non-folded area NFA2 forms a 2nd-1 comparison angle θ21′ with the virtual extension surface parallel to the first window surface WS1 of the second non-folded area NFA2. Each of the 1st-1 comparison angle θ11′ and the 2nd-1 comparison angle θ21′ is about 90°. Similarly, one end of the second protective layer R2 adjacent to the first non-folded area NFA1 forms a 1st-2 comparison angle θ12′ with the virtual extension surface parallel to the second window surface WS2 of the first non-folded area NFA1. The other end of the second protective layer R2 adjacent to the second non-folded area NFA2 forms a 2nd-2 comparison angle θ22′ with the virtual extension surface parallel to the second window surface WS2 of the second non-folded area NFA2. Each of the 1st-2 comparison angle θ12′ and the 2nd-2 comparison angle θ22′ is about 90°.

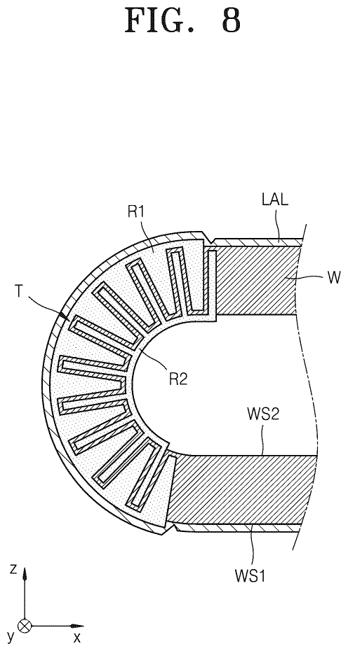

FIG. 8 illustrates deformation of a lower adhesive layer LAL when a display apparatus according to a comparative example is folded. As shown in FIG. 8, when a display apparatus according to a comparative example is folded, the thickness of a portion of the lower adhesive layer LAL attached to the first window surface WS1 of the window W is reduced. For example, when folding the display apparatus, tensile stress is applied to the lower adhesive layer LAL. Accordingly, the thickness of a portion of the lower adhesive layer LAL disposed adjacent to a portion of the first protective layer R1 where a step exists is reduced. Accordingly, the adhesive strength of the portion of the lower adhesive layer LAL, which has a reduced thickness, decreases, and thus, a portion of a component, such as the display panel 10, attached to the cover window CW by the lower adhesive layer LAL can detach from the cover window CW.

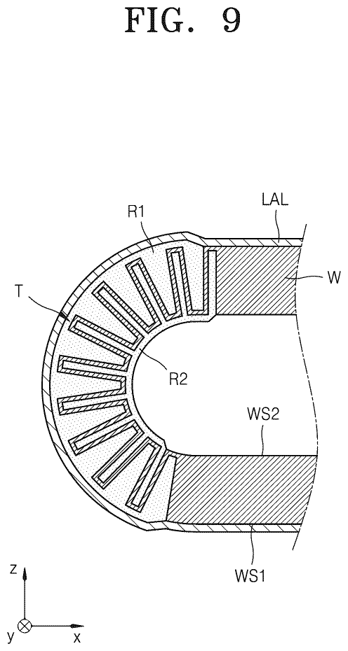

However, for the display apparatus 1 according to a present embodiment, the first protective layer R1 has a slope. Accordingly, when the display apparatus 1 is in-folded, even when tensile stress is applied to the lower adhesive layer LAL, the lower adhesive layer LAL moves along the slope of the first protective layer R1. Therefore, as shown in FIG. 9, which illustrates the deformation of the lower adhesive layer LAL when folding the display apparatus 1 according to an embodiment, the thickness of a portion of the lower adhesive layer LAL is not reduced and the lower adhesive layer LAL has a uniform thickness as a whole. For example, the adhesive strength of the portion of the lower adhesive layer LAL does not decrease, and a portion of a component, such as the display panel 10, attached to the cover window CW by the lower adhesive layer LAL does not detach from the cover window CW. For example, when the display apparatus 1 is in-folded, a portion of a component, such as a display panel 10, attached to the cover window CW does not detach from the cover window CW.

In addition, for the display apparatus 1 according to a present embodiment, the second protective layer R2 also has a slope. Accordingly, even when the display apparatus 1 is in an out-folding state in which a display surface is externally exposed, the upper adhesive layer UAL moves along the slope of the second protective layer R2. Accordingly, the thickness of a portion of the upper adhesive layer UAL is not reduced, and the upper adhesive layer UAL has a uniform thickness as a whole. For example, the adhesive strength of a portion of the upper adhesive layer UAL does not decrease, and a portion of a component, such as the protective film PF, attached to the cover window CW by the upper adhesive layer UAL does not detach from the cover window CW. For example, when the display apparatus 1 is out-folded, a portion of a component, such as the protective film PF, attached to the cover window CW does not detach from the cover window CW.

Although FIGS. 5 and 6 show that there is one 1st-1 trench T11, one 1st-2 trench T12, one 2nd-1 trench T21, and one 2nd-2 trench T22, embodiments of the disclosure are not necessarily limited thereto. For example, a plurality of each of the 1st-1 trench T11, the 1st-2 trench T12, the 2nd-1 trench T21, and the 2nd-2 trench T22 may be provided.

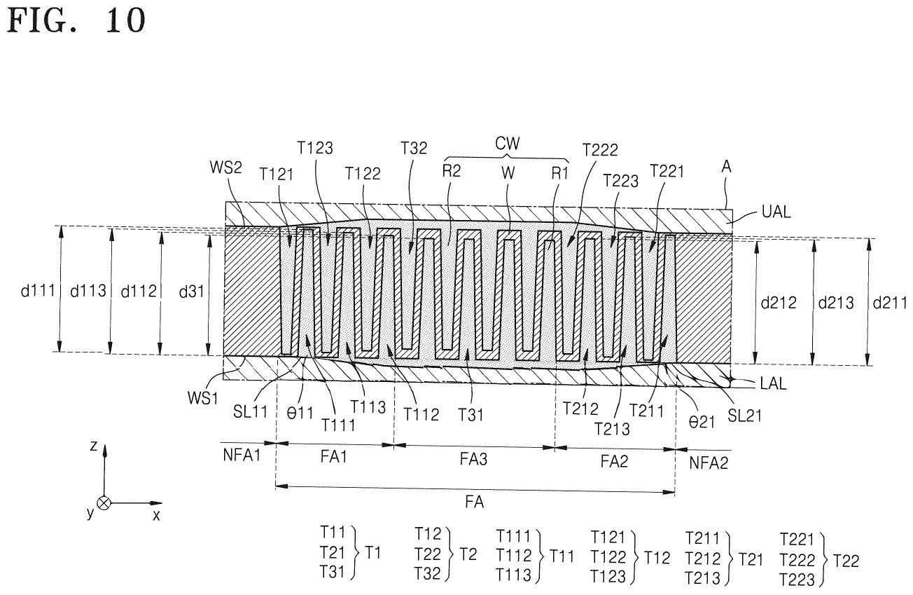

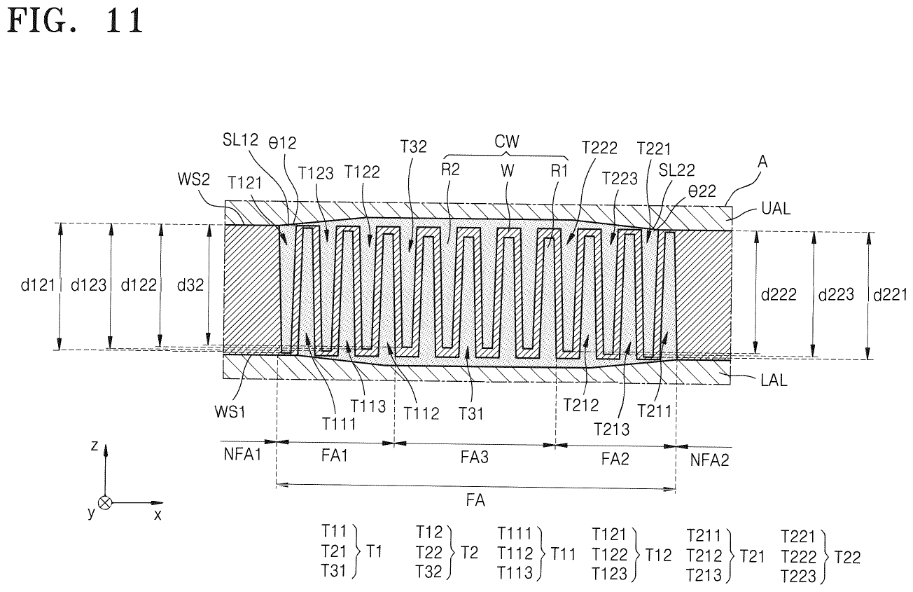

FIG. 10 is a schematic cross-sectional view of a portion of the display apparatus 1 according to an embodiment. FIG. 11 is a schematic cross-sectional view of a portion of the display apparatus 1 according to an embodiment.

As shown in FIG. 10, in an embodiment, the 1st-1 trench T11 includes a 1st-1-1 trench T111, a 1st-1-2 trench T112, and a 1st-1-3 trench T113. The 1st-1-1 trench T111 is formed in a portion of the first foldable area FA1 adjacent to the first non-folded area NFA1, and the 1st-1-2 trench T112 is formed in a portion of the first foldable area FA1 adjacent to the third foldable area FA3. The 1st-1-3 trench T113 is formed in a portion of the first foldable area FA1 between the portion of the first foldable area FA1 where the 1st-1-1 trench T111 is formed and the portion of the first foldable area FA1 where the 1st-1-2 trench T112 is formed. For example, in a plan view, the 1st-1-1 trench T111 is formed adjacent to the first non-folded area NFA1, the 1st-1-2 trench T112 is formed adjacent to the third foldable area FA3, and the 1st-1-3 trench T113 is formed between the 1st-1-1 trench T111 and the 1st-1-2 trench T112.

The 2nd-1 trench T21 includes a 2nd-1-1 trench T211, a 2nd-1-2 trench T212, and a 2nd-1-3 trench T213. The 2nd-1-1 trench T211 is formed in a portion of the second foldable area FA2 adjacent to the second non-folded area NFA2, and the 2nd-1-2 trench T212 is formed in a portion of the second foldable area FA2 adjacent to the third foldable area FA3. The 2nd-1-3 trench T213 is formed in a portion of the second foldable area FA2 between the portion of the second foldable area FA2 where the 2nd-1-1 trench T211 is formed and the portion of the second foldable area FA2 where the 2nd-1-2 trench T212 is formed. For example, in a plan view, the 2nd-1-1 trench T211 is formed adjacent to the second non-folded area NFA2, the 2nd-1-2 trench T212 is formed adjacent to the third foldable area FA3, and the 2nd-1-3 trench T213 is formed between the 2nd-1-1 trench T211 and the 2nd-1-2 trench T212.

The 1st-1-1 trench T111 has a 1st-1-1 depth d111, the 1st-1-2 trench T112 has a 1st-1-2 depth d112, and the 1st-1-3 trench T113 has a 1st-1-3 depth d113. The 1st-1-3 depth d113 is greater than the 1st-1-2 depth d112, and the 1st-1-1 depth d111 is greater than the 1st-1-3 depth d113. In addition, the 1st-1-2 depth d112 is greater than the 3rd-1 depth d31. The 2nd-1-1 trench T211 has a 2nd-1-1 depth d211, the 2nd-1-2 trench T212 has a 2nd-1-2 depth d212, and the 2nd-1-3 trench T213 has a 2nd-1-3 depth d213. The 2nd-1-3 depth d213 is greater than the 2nd-1-2 depth d212, and the 2nd-1-1 depth d211 is greater than the 2nd-1-3 depth d213.

For example, the depth of the 1st-1 trench T11 increases from the third foldable area FA3 to the first non-folded area NFA1, and the depth of the 2nd-1 trench T21 increases from the third foldable area FA3 to the second non-folded area NFA2. For example, the depth of the 1st-1 trench T11 decreases from the first non-folded area NFA1 to the third foldable area FA3, and the depth of the 2nd-1 trench T21 decreases from the second non-folded area NFA2 to the third foldable area FA3. In addition, the 1st-1 angle θ11 of the 1st-1 slope SL11 is further reduced, and the 2nd-1 angle θ21 of the 2nd-1 slope SL21 is further reduced. Accordingly, the lower adhesive layer LAL can move more easily along the slope of the first protective layer R1. For example, when the display apparatus 1 is folded, a portion of a component, such as the display panel 10, attached to the cover window CW does not detach from the cover window CW.

As shown in FIG. 11, in an embodiment, the 1st-2 trench T12 includes a 1st-2-1 trench T121, a 1st-2-2 trench T122, and a 1st-2-3 trench T123. The 1st-2-1 trench T121 is formed in a portion of the first foldable area FA1 adjacent to the first non-folded area NFA1, and the 1st-2-2 trench T122 is formed in a portion of the first foldable area FA1 adjacent to the third foldable area FA3. The 1st-2-3 trench T123 is formed in a portion of the first foldable area FA1 between the portion of the first foldable area FA1 where the 1st-2-1 trench T121 is formed and the portion of the first foldable area FA1 where the 1st-2-2 trench T122 is formed. For example, in a plan view, the 1st-2-1 trench T121 is formed adjacent to the first non-folded area NFA1, the 1st-2-2 trench T122 is formed adjacent to the third foldable area FA3, and the 1st-2-3 trench T123 is formed between the 1st-2-1 trench T121 and the 1st-2-2 trench T122.

The 2nd-2 trench T22 includes a 2nd-2-1 trench T221, a 2nd-2-2 trench T222, and a 2nd-2-3 trench T223. The 2nd-2-1 trench T221 is formed in a portion of the second foldable area FA2 adjacent to the second non-folded area NFA2, and the 2nd-2-2 trench T222 is formed in a portion of the second foldable area FA2 adjacent to the third foldable area FA3. The 2nd-2-3 trench T223 is formed in a portion of the second foldable area FA2 between the portion of the second foldable area FA2 where the 2nd-2-1 trench T221 is formed and the portion of the second foldable area FA2 where the 2nd-2-2 trench T222 is formed. For example, in a plan view, the 2nd-2-1 trench T221 is formed adjacent to the second non-folded area NFA2, the 2nd-2-2 trench T222 is formed adjacent to the third foldable area FA3, and the 2nd-2-3 trench T223 is formed between the 2nd-2-1 trench T221 and the 2nd-2-2 trench T222.

The 1st-2-1 trench T121 has a 1st-2-1 depth d121, the 1st-2-2 trench T122 has a 1st-2-2 depth d122, and the 1st-2-3 trench T123 has a 1st-2-3 depth d123. The 1st-2-3 depth d123 is greater than the 1st-2-2 depth d122, and the 1st-2-1 depth d121 is greater than the 1st-2-3 depth d123. In addition, the 1st-2-2 depth d122 is greater than the 3rd-2 depth d32. The 2nd-2-1 trench T221 has a 2nd-2-1 depth d221, the 2nd-2-2 trench T222 has a 2nd-2-2 depth d222, and the 2nd-2-3 trench T223 has a 2nd-2-3 depth d223. The 2nd-2-3 depth d223 is greater than the 2nd-2-2 depth d222, and the 2nd-2-1 depth d221 is greater than the 2nd-2-3 depth d223.

For example, the depth of the 1st-2 trench T12 increases from the third foldable area FA3 to the first non-folded area NFA1, and the depth of the 2nd-2 trench T22 increases from the third foldable area FA3 to the second non-folded area NFA2. For example, the depth of the 1st-2 trench T12 decreases from the first non-folded area NFA1 to the third foldable area FA3, and the depth of the 2nd-2 trench T22 decreases from the second non-folded area NFA2 to the third foldable area FA3. In addition, the 1st-2 angle θ12 of the 1st-2 slope SL12 is further reduced, and the 2nd-2 angle θ22 of the 2nd-2 slope SL22 is further reduced. Accordingly, the upper adhesive layer UAL can move more easily along the slope of the second protective layer R2. For example, when the display apparatus 1 is folded, a portion of a component, such as the protective film PF, attached to the cover window CW does not detach from the cover window CW.

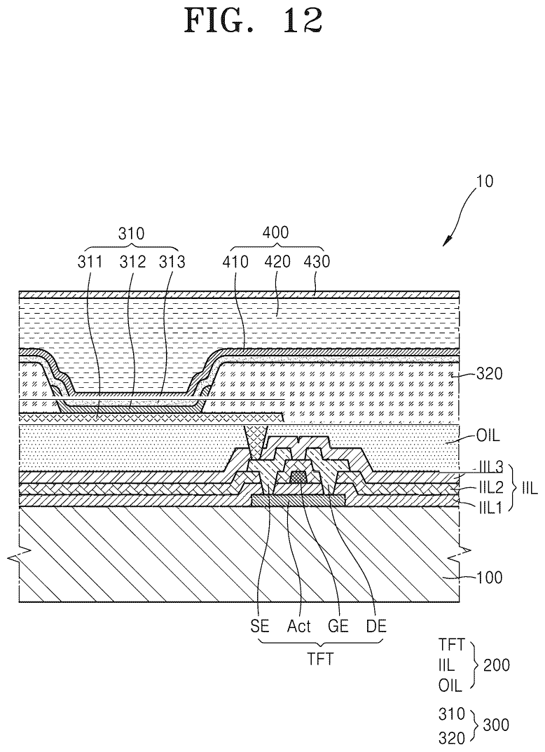

FIG. 12 is a schematic cross-sectional view of a portion of the display panel 10 in the display apparatus 1 according to an embodiment. As recognized by those of ordinary skill in the art, the display panel 10 may have various configurations other than that shown in FIG. 12.

As shown in FIG. 12, in an embodiment, the display panel 10 includes a substrate 100, a pixel circuit layer 200, a display element layer 300, and an encapsulation layer 400. The substrate 100 includes at least one of glass, metal, or polymer resin. The substrate 100 is flexible or bendable. For example, the substrate 100 includes a polymer resin, such as at least one of polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure that includes two layers that each include the polymer resin, and a barrier layer that includes an inorganic material, such as one of silicon oxide (SiOₓ), silicon nitride (SiNₓ), or silicon oxynitride (SiOₓN_{y}) between the two layers. However, embodiments are not necessarily limited thereto, and various modifications can be made in other embodiments.

The pixel circuit layer 200 is disposed on the substrate 100. The pixel circuit layer 200 includes a thin-film transistor TFT, an inorganic insulating layer IIL, and an organic insulating layer OIL. The thin-film transistor TFT includes a semiconductor layer Act, a gate electrode GE, a source electrode SE, and a drain electrode DE. The inorganic insulating layer IIL includes a gate insulating layer IIL1, a first interlayer insulating layer IIL2, and a second interlayer insulating layer IIL3.

The semiconductor layer Act is disposed on the substrate 100. In an embodiment, the semiconductor layer Act includes polysilicon. In other embodiments, the semiconductor layer Act includes at least one of amorphous silicon, an oxide semiconductor, or an organic semiconductor, etc. In an embodiment, the semiconductor layer Act includes a channel region, and a source region and a drain region respectively disposed on each side of the channel region.

The gate insulating layer IIL1 is disposed on the semiconductor layer Act and the substrate 100. The gate insulating layer IIL1 includes an inorganic insulating material, such as at least one of silicon oxide (SiO_{X}), silicon nitride (SiN_{X}), silicon oxynitride (SiO_{X}N_{Y}), aluminum oxide (Al₂O₃), titanium oxide (TiO₂), tantalum oxide (Ta₂O₅), hafnium oxide (HfO₂), or zinc oxide (ZnOx). Zinc oxide (ZnO_{X}) includes at least one of zinc oxide (ZnO) and/or zinc peroxide (ZnO₂).

The gate electrode GE is disposed on the gate insulating layer IIL1. For example, as the gate insulating layer IIL1 is disposed between the semiconductor layer Act and the gate electrode GE, insulation between the semiconductor layer Act and the gate electrode GE is secured. The gate electrode GE overlaps the channel region of the semiconductor layer Act. The gate electrode GE includes a low-resistance metal. In an embodiment, the gate electrode GE includes a conductive material that includes at least one of molybdenum (Mo), aluminum (Al), copper (Cu), or titanium (Ti), etc., and may have a single-layered or a multi-layered structure that includes the conductive material.

The first interlayer insulating layer IIL2 is disposed on the gate electrode GE and the gate insulating layer IIL1. The first interlayer insulating layer IIL2 includes an inorganic insulating material, such as at least one of SiO_{X}, SiN_{X}, SiO_{X}N_{Y}, Al₂O₃, TiO₂, Ta₂O₅, HfO₂, or ZnOx.

The source electrode SE and the drain electrode DE are disposed on the first interlayer insulating layer IIL2. Each of the source electrode SE and the drain electrode DE is connected to the semiconductor layer Act through a contact hole formed in the gate insulating layer IIL1 and the first interlayer insulating layer IIL2. At least one of the source electrode SE or the drain electrode DE includes a conductive material, such as at least one of Mo, Al, Cu, or Ti, etc., and may have a single-layered or a multi-layered structure that includes the conductive material. In an embodiment, at least one of the source electrode SE or the drain electrode DE has a multi-layered structure that includes Ti/Al/Ti layers.

The second interlayer insulating layer IIL3 is disposed on the source electrode SE, the drain electrode DE, and the first interlayer insulating layer IIL2. The second interlayer insulating layer IIL3 includes an inorganic insulating material, such as at least one of SiO_{X}, SiN_{X}, SiO_{X}N_{Y}, Al₂O₃, TiO₂, Ta₂O₅, HfO₂, or ZnOx.

The organic insulating layer OIL is disposed on the second interlayer insulating layer IIL3. The organic insulating layer OIL substantially planarizes an upper portion of the pixel circuit layer 200. The organic insulating layer OIL includes an organic material, such as at least one of acrylic, benzocyclobutene (BCB), or hexamethyldisiloxane (HMDSO). Although FIG. 10 shows that the organic insulating layer OIL includes a single layer, various modifications, such as multiple layers, may be made.

In addition, the pixel circuit layer 200 may include a storage capacitor. Although FIG. 12 shows that the pixel circuit layer 200 includes one transistor, embodiments of the disclosure are not necessarily limited thereto. For example, the number of transistors or the number of storage capacitors can vary depending on the design of the pixel circuit layer 200.

The display element layer 300 is disposed on the pixel circuit layer 200. The display element layer 300 includes a display element 310 and a pixel-defining layer 320. The display element 310 is electrically connected to the thin-film transistor TFT. The display element 310 may be, for example, an organic light-emitting diode that includes a pixel electrode 311, an opposite electrode 313, and an intermediate layer 312 placed therebetween and that includes an emission layer. The fact that the display element 310 is electrically connected to the thin-film transistor TFT may be understood as the fact that the pixel electrode 311 of the organic light-emitting diode is electrically connected to the thin-film transistor TFT.

The pixel electrode 311 is electrically connected to the thin-film transistor TFT by contacting either the source electrode SE or the drain electrode DE through a contact hole formed in the second interlayer insulating layer IIL3 and the organic insulating layer OIL. The pixel electrode 311 includes a conductive oxide, such as at least one of indium tin oxide (ITO), indium zinc oxide (IZO), zinc oxide (ZnO), indium oxide (In₂O₃), indium gallium oxide (IGO), or aluminum zinc oxide (AZO). In an embodiment, the pixel electrode 311 includes a reflective layer that includes at least one of silver (Ag), magnesium (Mg), aluminum (Al), platinum (Pt), palladium (Pd), gold (Au), nickel (Ni), neodymium (Nd), iridium (Ir), chromium (Cr) or a compound thereof. In an embodiment, the pixel electrode 311 further includes a layer that includes at least one of ITO, IZO, ZnO, or In₂O₃ above/below the reflective layer.

The pixel-defining layer 320 covers an edge of the pixel electrode 311. The pixel-defining layer 320 includes a pixel opening, and the pixel opening overlaps the pixel electrode 311. The pixel opening defines an emission area of light emitted from the display element 310. The pixel-defining layer 320 includes an organic insulating material and/or an inorganic insulating material. In some embodiments, the pixel-defining layer 320 includes a light blocking material.

The intermediate layer 312 is disposed on the pixel electrode 311 and the pixel-defining layer 320. The intermediate layer 312 includes a low molecular weight or high molecular weight material. When the intermediate layer 312 includes a low molecular weight material, the intermediate layer 312 has a structure in which a hole injection layer (HIL), a hole transport layer (HTL), an emission layer (EML), an electron transport layer (ETL), an electron injection layer (EIL), etc., are stacked in a single or complex structure, and are formed by a vacuum deposition method. When the intermediate layer 312 includes a high molecular weight material, the intermediate layer 312 has a structure that includes an HTL and an EML. For example, the HTL includes PEDOT, and the EML includes a high molecular weight material such as at least one of polyphenylene vinylene (PPV) or polyfluorene. The intermediate layer 312 can be formed by screen printing, inkjet printing, laser induced thermal imaging (LITI), etc. The intermediate layer 312 is not necessarily limited thereto and may have various other structures in other embodiments. Furthermore, the intermediate layer 312 may include a layer that extends across a plurality of pixel electrodes 311, or may include a layer patterned to correspond to each of the plurality of pixel electrodes 311.

The opposite electrode 313 is disposed on the intermediate layer 312 and the pixel-defining layer 320. The opposite electrode 313 is integrally formed in a plurality of organic light-emitting diodes and corresponds to a plurality of pixel electrodes 311. The opposite electrode 313 includes a light-transmitting conductive layer that includes at least one of ITO, In₂O₃, or IZO, and may also include a semi-transmissive layer that includes a metal, such as Al or Ag. For example, the opposite electrode 313 is a semi-transmissive layer that includes Mg or Ag.

The display element 310 can be easily damaged by external moisture or oxygen, and thus, the encapsulation layer 400 covers the display element 310 to protect the display element 310. As shown in FIG. 12, the encapsulation layer 400 includes a first inorganic encapsulation layer 410, an organic encapsulation layer 420, and a second inorganic encapsulation layer 430.

The first inorganic encapsulation layer 410 covers the opposite electrode 313 and includes at least one of SiO_{X}, SiN_{X}, and/or SiO_{X}N_{Y}. As needed, other layers, such as a capping layer, can be disposed between the first inorganic encapsulation layer 410 and the opposite electrode 313. Because the first inorganic encapsulation layer 410 is formed along a structure thereunder, the upper surface of the first inorganic encapsulation layer 410 is not flat, as shown in FIG. 12. The organic encapsulation layer 420 covers the first inorganic encapsulation layer 410, and unlike the first inorganic encapsulation layer 410, the upper surface of the organic encapsulation layer 420 is substantially flat. The organic encapsulation layer 420 includes one or more of polyethyleneterephthalate, polyethylenenaphthalate, polycarbonate, polyimide, polyethylenesulfonate, polyoxymethylene, polyarylate, or hexamethyldisiloxane. The second inorganic encapsulation layer 430 covers the organic encapsulation layer 420, and includes at least one of SiO_{X}, SiN_{X}, and/or SiO_{X}N_{Y}.

As described above, the encapsulation layer 400 includes the first inorganic encapsulation layer 410, the organic encapsulation layer 420, and the second inorganic encapsulation layer 430, and thus, even when a crack occurs through the multi-layered structure of the encapsulation layer 400, the crack can be disconnected between the first inorganic encapsulation layer 410 and the organic encapsulation layer 420 or between the organic encapsulation layer 420 and the second inorganic encapsulation layer 430. Accordingly, the formation of a path through which external moisture or oxygen can penetrate into the display panel 10 can be prevented or reduced.

Although the display apparatus 1 has been described above, embodiments of disclosure are not necessarily limited thereto. It may be said that a method of manufacturing the display apparatus 1 also falls within the scope of the disclosure. Hereinafter, a method of manufacturing the display apparatus 1 will be described.

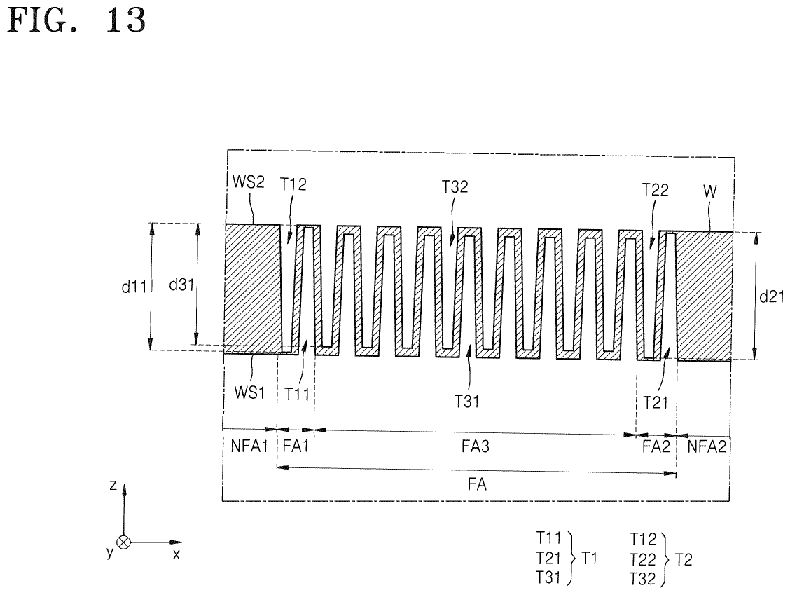

FIGS. 13 to 18 are schematic cross-sectional views that illustrate a process of manufacturing the display apparatus 1 of FIG. 3. For example, FIGS. 13 to 18 are schematic cross-sectional views that illustrate a process of forming the cover window CW of the display apparatus 1 of FIG. 3. In FIGS. 13 to 18, for convenience of explanation, a method of manufacturing the display apparatus 1 will be described based on the area A of the display apparatus 1 of FIG. 3. Hereinafter, in describing a process of manufacturing the display apparatus 1 of FIG. 3 with reference to FIGS. 13 to 18, the same reference numerals as those in FIGS. 1 to 6 may indicate the same members, and duplicate descriptions may be omitted.

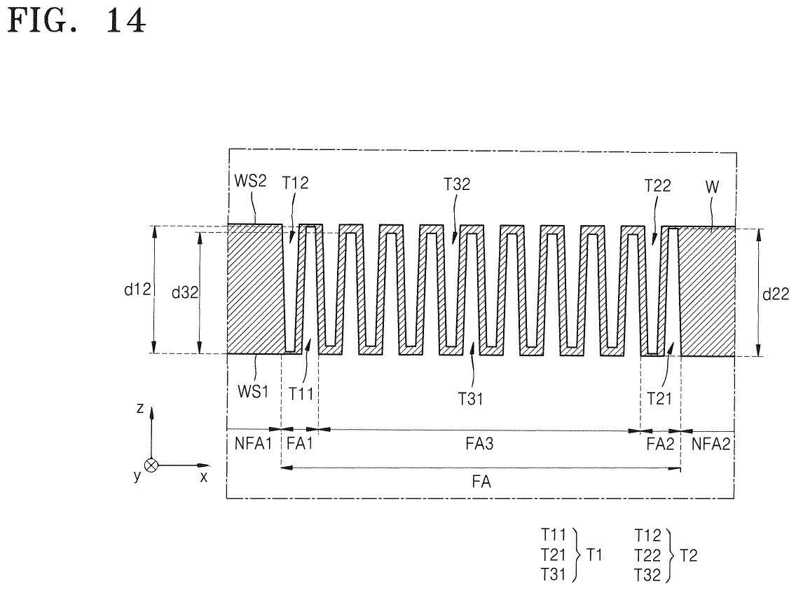

First, as shown in FIGS. 13 and 14, a window W is provided. The window W includes a first non-folded area NFA1, a second non-folded area NFA2, and a foldable area FA, and the window W has a first window surface WS1 and a second window surface WS2 opposite to the first window surface WS1. A plurality of trenches T are formed in the foldable area FA of the window W.

For example, the plurality of trenches T include first trenches T1 and second trenches T2. The first trenches T1 are formed in the first window surface WS1, and the second trenches T2 are formed in the second window surface WS2. In a plan view, the trenches T formed in the first window surface WS1 and the trenches T formed in the second window surface WS2 are alternately arranged. For example, in a plan view, the first trenches T1 and the second trenches T2 are alternately arranged.

The depths of a trench formed adjacent to the first non-folded area NFA1 and a trench T formed adjacent to the second non-folded area NFA2 are greater than the depth of a trench formed in a central area of the foldable area FA. As described above, the foldable area FA includes a first foldable area FA1, a second foldable area FA2, and a third foldable area FA3. The first foldable area FA1 is adjacent to the first non-folded area NFA1, and the second foldable area FA2 is adjacent to the second non-folded area NFA2. The third foldable area FA3 is disposed between the first foldable area FA1 and the second foldable area FA2.

The first trenches T1 include a 1st-1 trench T11 formed in the first foldable area FA1, a 2nd-1 trench T21 formed in the second foldable area FA2, and a 3rd-1 trench T31 formed in the third foldable area FA3. As shown in FIG. 13, the 1st-1 trench T11 has a 1st-1 depth d11, and the 3rd-1 trench T31 has a 3rd-1 depth d31. The 1st-1 depth d11 is greater than the 3rd-1 depth d31. The 2nd-1 trench T21 has a 2nd-1 depth d21, and the 2nd-1 depth d21 is greater than the 3rd-1 depth d31. As shown in FIG. 14, the second trenches T2 include a 1st-2 trench T12 formed in the first foldable area FA1, a 2nd-2 trench T22 formed in the second foldable area FA2, and a 3rd-2 trench T32 formed in the third foldable area FA3. The 1st-2 trench T12 has a 1st-2 depth d12, and the 3rd-2 trench T32 has a 3rd-2 depth d32. The 1st-2 depth d12 is greater than the 3rd-2 depth d32. The 2nd-2 trench T22 has a 2nd-2 depth d22, and the 2nd-2 depth d22 is greater than the 3rd-2 depth d32. Because forming the trench T in the window W is a common aspect in manufacturing a display apparatus, detailed descriptions thereof are omitted.

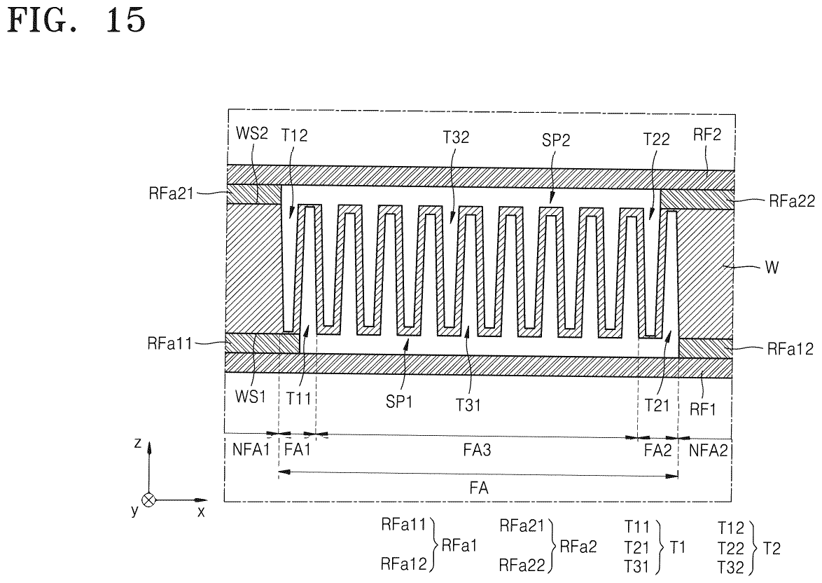

Next, as shown in FIG. 15, a release film is attached to the window W by using a release film adhesive layer. For example, a first release film RF1 is attached to the window W by using a first release film adhesive layer RFa1 disposed on the first window surface WS1 of the first non-folded area NFA1 and the second non-folded area NFA2. For example, the first release film adhesive layer RFa1 includes a 1st-1 release film adhesive layer RFa11 and a 1st-2 release film adhesive layer RFa12. The 1st-1 release film adhesive layer RFa11 is disposed between the first release film RF1 and the first non-folded area NFA1, and the 1st-2 release film adhesive layer RFa12 is disposed between the first release film RF1 and the second non-folded area NFA2. For example, the 1st-1 release film adhesive layer RFa11 is disposed adjacent to the 1st-1 trench T11, and the 1st-2 release film adhesive layer RFa12 is disposed adjacent to the 2nd-1 trench T21.

Accordingly, a gap equal to the thickness of the first release film adhesive layer RFa1 is formed between the first window surface WS1 of the foldable area FA and the upper surface (in the +z direction) of the first release film RF1. Accordingly, in a cross-sectional view taken along a plane that is perpendicular to the window W and passes through the first release film adhesive layer RFa1, the first release film RF1, and a portion of the window W that forms the first trenches T1, a first space SP1 is defined that is surrounded by the first release film adhesive layer RFa1, the first release film RF1, and the portion of the window W that formed the first trenches T1.

Similarly, a second release film RF2 is attached to the window W by using a second release film adhesive layer RFa2 disposed on the second window surface WS2 of the first non-folded area NFA1 and the second non-folded area NFA2. For example, the second release film adhesive layer RFa2 includes a 2nd-1 release film adhesive layer RFa21 and a 2nd-2 release film adhesive layer RFa22. The 2nd-1 release film adhesive layer RFa21 is disposed between the second release film RF2 and the first non-folded area NFA1, and the 2nd-2 release film adhesive layer RFa22 is disposed between the second release film RF2 and the second non-folded area NFA2. For example, the 2nd-1 release film adhesive layer RFa21 is disposed adjacent to the 1st-2 trench T12, and the 2nd-2 release film adhesive layer RFa22 is disposed adjacent to the 2nd-2 trench T22.

Accordingly, a gap equal to the thickness of the second release film adhesive layer RFa2 is formed between the second window surface WS2 of the foldable area FA and the lower surface (in the −z direction) of the second release film RF2. Accordingly, in a cross-sectional view taken along a plane that is perpendicular to the window W and passes through the second release film adhesive layer RFa2, the second release film RF2, and a portion of the window W that forms the second trenches T2, a second space SP2 is defined that is surrounded by the second release film adhesive layer RFa2, the second release film RF2, and the portion of the window W formed the second trenches T2.

The first release film RF1 and the second release film RF2 each include at least one of polyethylene terephthalate (PET), polyimide (PI), polyamide-imide (PAI), polypropylene (PP), or polystyrene (PS), etc. However, embodiments of the disclosure are not necessarily limited thereto. As described below, a configuration that defines a space filled with a protective layer composition may be used in the first release film RF1 and the second release film RF2 without limitation. Each of the first release film adhesive layer RFa1 and the second release film adhesive layer RFa2 includes an adhesive member, such as an OCA or a PSA.

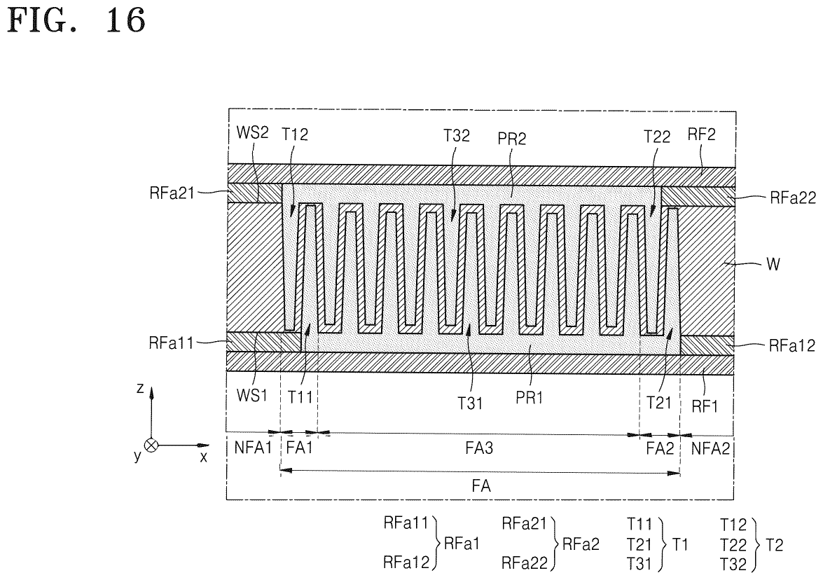

FIG. 16 is a cross-sectional view taken along a plane that is perpendicular to the window W and passes through a release film adhesive layer, a release film, and a portion of the window W in which a plurality of trenches T are formed. As shown in FIG. 16, a space is formed that is surrounded by the release film adhesive layer, the release film, and the portion of the window W in which the plurality of trenches T is formed, and the space is filled with a protective layer composition.

For example, the first space SP1 is filled with a first protective layer composition PR1. The first protective layer composition PR1 fills in the first space SP1 by capillary force. For example, the first protective layer composition PR1 fills in the first trenches T1 and a gap between the first window surface WS1 of the foldable area FA and the upper surface (in the +z direction) of the first release film RF1 by capillary force. Because the depth of the 1st-1 trench T11 is greater than that of the 3rd-1 trench T31, a volume of the first protective layer composition PR1 filled in the 1st-1 trench T11 is greater than a volume of the first protective layer composition PR1 filled in the 3rd-1 trench T31. Because the depth of the 2nd-1 trench T21 is greater than that of the 3rd-1 trench T31, a volume of the first protective layer composition PR1 filled in the 2nd-1 trench T21 is greater than a volume of the first protective layer composition PR1 filled in the 3rd-1 trench T31.

The first protective layer composition PR1 includes a monomer and/or polymer that form the first protective layer R1. The first protective layer R1 includes at least one of a silicone-based resin, an OCR, or an OCA. For example, the first protective layer R1 is formed by curing the first protective layer composition PR1. The first protective layer composition PR1 may further include a photocuring agent. The first protective layer composition PR1 includes, but is not particularly limited to, a photocuring agent as long as the photocuring agent can be used to photocure the monomer and/or polymer for forming the first protective layer R1. In an embodiment, the first protective layer composition PR1 further includes a solvent. The solvent in the first protective layer composition PR1 is any solvent that can dissolve the monomer and/or polymer that form the first protective layer R1, and is not particularly limited. For example, the first protective layer composition PR1 is a solution in which a monomer and/or polymer that form the first protective layer R1 and a photocuring agent are dissolved in a solvent.

Similarly, the second space SP2 is filled with a second protective layer composition PR2. The second protective layer composition PR2 fills in the second space SP2 by capillary force. For example, the second protective layer composition PR2 fills in the second trenches T2 and a gap between the second window surface WS2 of the foldable area FA and the lower surface (in the −z direction) of the second release film RF2 by capillary force. Because the depth of the 1st-2 trench T12 is greater than that of the 3rd-2 trench T32, a volume of the second protective layer composition PR2 filled in the 1st-2 trench T12 is greater than a volume of the second protective layer composition PR2 filled in the 3rd-2 trench T32. Because the depth of the 2nd-2 trench T22 is greater than that of the 3rd-2 trench T32, a volume of the second protective layer composition PR2 filled in the 2nd-2 trench T22 is greater than a volume of the second protective layer composition PR2 filled in the 3rd-2 trench T32.

The second protective layer composition PR2 includes a monomer and/or polymer that form the second protective layer R2. The second protective layer R2 includes at least one of a silicone-based resin, an OCR, or an OCA. For example, the second protective layer R2 is formed by curing the second protective layer composition PR2. The second protective layer composition PR2 may further include a photocuring agent. The second protective layer composition PR2 includes, but is not particularly limited to, a photocuring agent as long as the photocuring agent can be used to photocure the monomer and/or polymer that form the second protective layer R2. In an embodiment, the second protective layer composition PR2 further includes a solvent. The solvent in the second protective layer composition PR2 is any solvent that can dissolve the monomer and/or polymer that form the second protective layer R2, and is not particularly limited. For example, the second protective layer composition PR2 is a solution in which a monomer and/or polymer that form the second protective layer R2 and a photocuring agent are dissolved in a solvent.

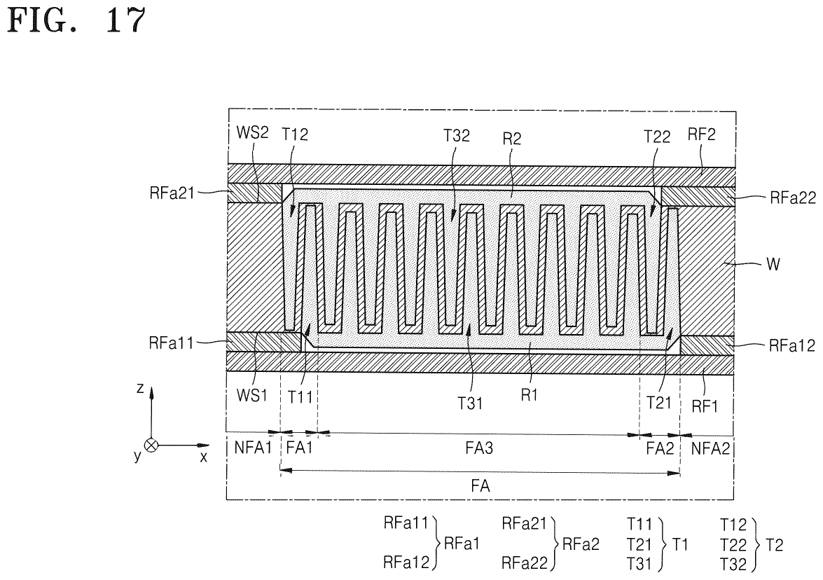

Next, as shown in FIG. 17, ultraviolet light is irradiated onto the protective layer composition. For example, the first protective layer R1 is formed by irradiating ultraviolet light onto the first protective layer composition PR1, and the second protective layer R2 is formed by irradiating ultraviolet light onto the second protective layer composition PR2. For example, ultraviolet light that has a light intensity of between about 100 mJ/cm² and about 1,000 mJ/cm² is irradiated onto the first protective layer composition PR1 and the second protective layer composition PR2. Ultraviolet light that has a wavelength of between about 300 nm and about 400 nm is used for photocuring. A light-emitting diode (LED) or metal halide can be used as an ultraviolet source.

The volume of the first protective layer R1 is less than the volume of a first protective layer composition used to form the first protective layer R1. For example, the first protective layer R1 has contracted. In general, the larger the volume of a composition, the greater the degree of contraction of a layer formed by the composition. Because the volume of the first protective layer composition PR1 filled in the 1st-1 trench T11 is greater than the volume of the first protective layer composition PR1 filled in the 3rd-1 trench T31, the degree of contraction of the first protective layer R1 that fills the 1st-1 trench T11 is greater than the degree of contraction of the first protective layer R1 that fills the 3rd-1 trench T31. Therefore, the volume of a portion of the first protective layer R1 formed by the first protective layer composition PR1 that fills a space below the 1st-1 trench T11 and the 1st-1 trench T11 is greater than the volume of a portion of the first protective layer R1 formed by the first protective layer composition PR1 that fills a space below the 3rd-1 trench T31 and the 3rd-1 trench T31.

Accordingly, the shortest distance between a virtual extension surface parallel to the first window surface WS1 and the lower surface (in the −z direction) of a portion of the first protective layer R1 disposed below the 1st-1 trench T11 is less than the shortest distance between the virtual extension surface parallel to the first window surface WS1 and the lower surface (in the −z direction) of a portion of the first protective layer R1 disposed below the 3rd-1 trench T31. For example, a portion of the first protective layer R1 disposed below a portion of the foldable area FA adjacent to the first non-folded area NFA1 has a slope.

The above description of the shortest distance between the virtual extension surface parallel to the first window surface WS1 and the lower surface (in the −z direction) of a portion of the first protective layer R1 disposed below the 1st-1 trench T11 also applies to the shortest distance between the virtual extension surface parallel to the first window surface WS1 and the lower surface (in the −z direction) of a portion of the first protective layer R1 disposed below the 2nd-1 trench T21. Accordingly, another portion of the first protective layer R1 disposed below a portion of the foldable area FA adjacent to the second non-folded area NFA2 has a slope.

Similarly, because the volume of the second protective layer composition PR2 filled in the 1st-2 trench T12 is greater than the volume of the second protective layer composition PR2 filled in the 3rd-2 trench T32, the degree of contraction of the second protective layer R2 that fills the 1st-2 trench T12 is greater than the degree of contraction of the second protective layer R2 that fills the 3rd-2 trench T32. Therefore, the volume of a portion of the second protective layer R2 formed by the second protective layer composition PR2 that fills a space above the 1st-2 trench T12 and the 1st-2 trench T12 is greater than the volume of a portion of the second protective layer R2 formed by the second protective layer composition PR2 that fills a space above the 3rd-2 trench T32 and the 3rd-2 trench T32.

Accordingly, the shortest distance between a virtual extension surface parallel to the second window surface WS2 and the upper surface (in the +z direction) of a portion of the second protective layer R2 disposed above the 1st-2 trench T12 is less than the shortest distance between the virtual extension surface parallel to the second window surface WS2 and the upper surface (in the +z direction) of a portion of the second protective layer R2 disposed above the 3rd-2 trench T32. For example, a portion of the second protective layer R2 disposed above a portion of the foldable area FA adjacent to the first non-folded area NFA1 has a slope.

The above description of the shortest distance between the virtual extension surface parallel to the second window surface WS2 and the upper surface (in the +Z direction) of a portion of the second protective layer R2 disposed above the 1st-2 trench T12 also applies to the shortest distance between the virtual extension surface parallel to the second window surface WS2 and the upper surface (in the +z direction) of a portion of the second protective layer R2 disposed above the 2nd-2 trench T22. Accordingly, another portion of the second protective layer R2 disposed above a portion of the foldable area FA adjacent to the second non-folded area NFA2 has a slope.

In an embodiment, before irradiating ultraviolet light onto the first protective layer composition PR1 and the second protective layer composition PR2, the first protective layer composition PR1 and the second protective layer composition PR2 are heated to remove the solvent contained in the first protective layer composition PR1 and the solvent contained in the second protective layer composition PR2. Thereafter, ultraviolet light is irradiated onto the first protective layer composition PR1 and the second protective layer composition PR2.

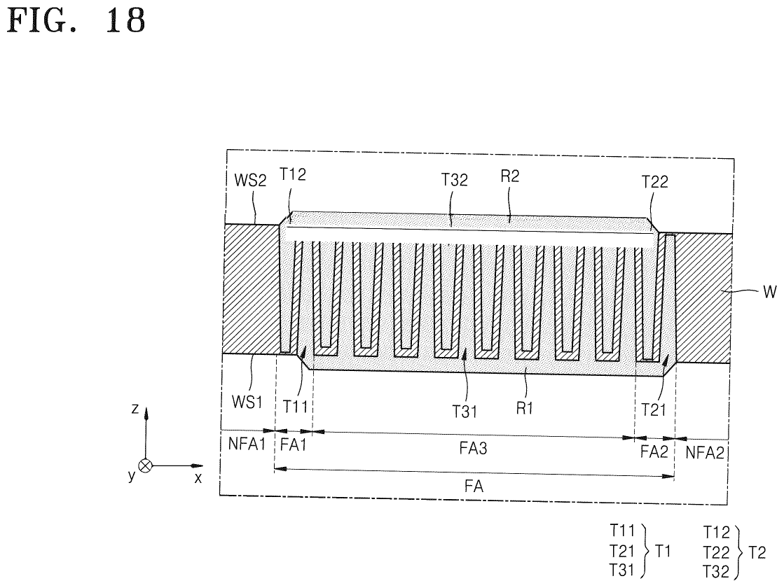

Next, as shown in FIG. 18, the adhesive layer and the release film are removed from the window W. For example, the first release film adhesive layer RFa1, the second release film adhesive layer RFa2, the first release film RF1, and the second release film RF2 are removed from the window W. Accordingly, a cover window CW that includes the window W, the first protective layer R1, and the second protective layer R2 is formed.

In the above described embodiments, a plurality of trenches T are alternately located on both sides of the window W. For example, part of the plurality of trenches T are formed in the first window surface WS1 and another part of the plurality of trenches T are formed in the second window surface WS2. However, embodiments of the disclosure are not necessarily limited thereto. In an embodiment, the plurality of trenches T are located on one side of the window W. For example, all of the plurality of trenches T are formed in one surface of the window W.

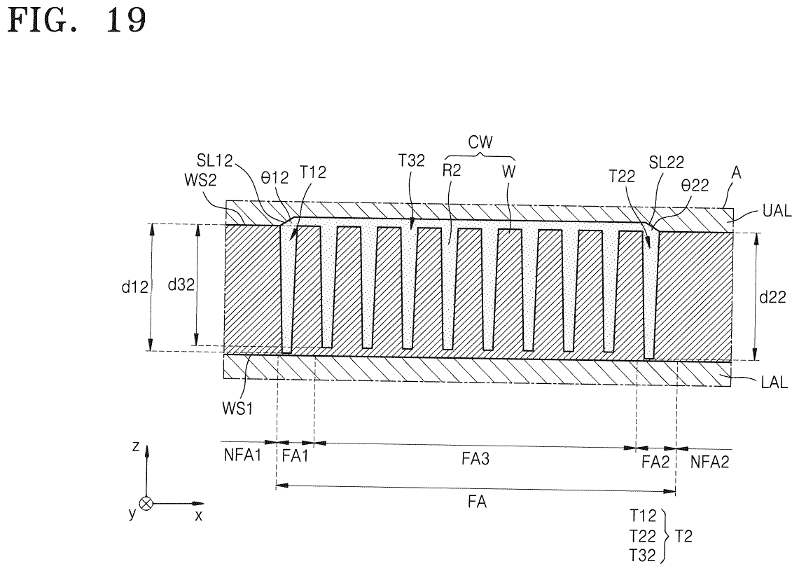

For example, as shown in FIG. 19, which is a schematic plan view of a portion of a display apparatus according to an embodiment, all of the plurality of trenches T are formed in the second window surface WS2. For example, the plurality of trenches T include second trenches T2, and the second trenches T2 include a 1st-2 trench T12, a 2nd-2 trench T22, and a 3rd-2 trench T32. The 1st-2 trench T12 is formed in the first foldable area FA1, the 2nd-2 trench T22 is formed in the second foldable area FA2, and the 3rd-2 trench T32 is formed in the third foldable area FA3. No trenches T are formed in the first window surface WS1. The cover window CW includes a second protective layer R2 but not a first protective layer R1.

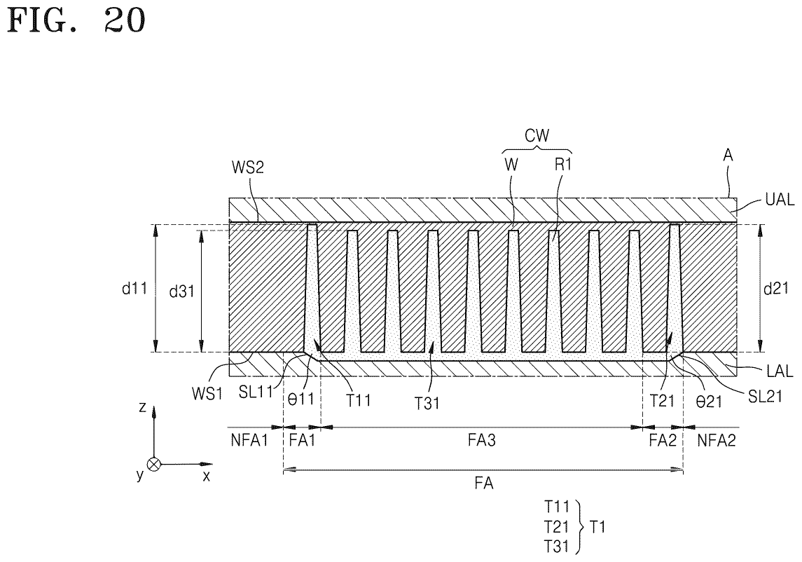

For example, as shown in FIG. 20, which is a schematic plan view of a portion of a display apparatus according to an embodiment, all of the plurality of trenches T are formed in the first window surface WS1. For example, the plurality of trenches T include first trenches T1, and the first trenches T1 include a 1st-1 trench T11, a 2nd-1 trench T21, and a 3rd-1 trench T31. The 1st-1 trench T11 is formed in the first foldable area FA1, the 2nd-1 trench T21 is formed in the second foldable area FA2, and the 3rd-1 trench T31 is formed in the third foldable area FA3. No trenches T are formed in the second window surface WS2. The cover window CW includes a first protective layer R1 but not a second protective layer R2.

According to embodiments of the disclosure as described above, a display apparatus in which a portion of a component attached to a cover window does not detached from the cover window when the display apparatus is folded, and a method of manufacturing the display apparatus, are implemented. However, the scope of embodiments of the disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus, comprising:
a display panel that includes display elements; and
a cover window disposed above the display panel and that includes a window, a first protective layer, and a second protective layer,
wherein the window includes a first non-folded area, a second non-folded area, and a foldable area between the first non-folded area and the second non-folded area,
a plurality of trenches are formed in the foldable area, and
depths of a trench formed adjacent to the first non-folded area and a trench formed adjacent to the second non-folded area are greater than a depth of a trench formed in a central area of the foldable area.

2. The display apparatus of claim 1, wherein the window includes a first window surface in a direction of the display panel and a second window surface in a direction opposite to the direction of the display panel,
the plurality of trenches include first trenches formed in the first window surface and second trenches formed in the second window surface, and
in a plan view, the first trenches and the second trenches are alternately arranged.

3. The display apparatus of claim 2, wherein
the foldable area includes a first foldable area adjacent to the first non-folded area, a second foldable area adjacent to the second non-folded area, and a third foldable area located between the first foldable area and the second foldable area,
the first trenches include a 1st-1 trench formed in the first foldable area, a 2nd-1 trench formed in the second foldable area, and a 3rd-1 trench formed by the third foldable area, and
a depth of the 1st-1 trench and a depth of the 2nd-1 trench are each greater than a depth of the 3rd-1 trench.

4. The display apparatus of claim 3, wherein the first protective layer is disposed below the foldable area, and a portion of the first protective layer has a slope.

5. The display apparatus of claim 4, wherein
a portion of the first protective layer disposed below the first foldable area has a 1st-1 slope, and
a portion of the first protective layer disposed below the second foldable area has a 2nd-1 slope.

6. The display apparatus of claim 3, wherein
the 1st-1 trench includes a 1st-1-1 trench, a 1st-1-2 trench, and a 1st-1-3 trench,
the 1st-1-1 trench is formed in a portion of the first foldable area adjacent to the first non-folded area,
the 1st-1-2 trench is formed in a portion of the first foldable area adjacent to the second foldable area,
the 1st-1-3 trench is formed in a portion of the first foldable area located between the portion of the first foldable area where the 1st-1-1 trench is formed and the portion of the first foldable area where the 1st-1-2 trench is formed,
a depth of the 1st-1-3 trench is greater than a depth of the 1st-1-2 trench, and
a depth of the 1st-1-1 trench is greater than the depth of the 1st-1-3 trench.

7. The display apparatus of claim 3, wherein
the 2nd-1 trench includes a 2nd-1-1 trench, a 2nd-1-2 trench, and a 2nd-1-3 trench,
the 2nd-1-1 trench is formed in a portion of the second foldable area adjacent to the second non-folded area,
the 2nd-1-2 trench is formed in a portion of the second foldable area adjacent to the third foldable area,
the 2nd-1-3 trench is formed in a portion of the second foldable area between the portion of the second foldable area where the 2nd-1-1 trench is formed and the portion of the second foldable area where the 2nd-1-2 trench is formed,
a depth of the 2nd-1-3 trench is greater than a depth of the 2nd-1-2 trench, and
a depth of the 2nd-1-1 trench is greater than the depth of the 2nd-1-3 trench.

8. The display apparatus of claim 3, further comprising a lower adhesive layer disposed between the display panel and the cover window.

9. The display apparatus of claim 3, wherein
the second trenches include a 1st-2 trench formed in the first foldable area, a 2nd-2 trench formed in the second foldable area, and a 3rd-2 trench formed in the third foldable area, and
a depth of the 1st-2 trench and a depth of the 2nd-2 trench are each greater than a depth of the 3rd-2 trench.

10. The display apparatus of claim 9, wherein
the second protective layer is disposed on the foldable area, and
a portion of the second protective layer has a slope.

11. The display apparatus of claim 10, wherein
a portion of the second protective layer disposed above the first foldable area has a 1st-2 slope, and
a portion of the second protective layer disposed above the second foldable area has a 2nd-2 slope.

12. The display apparatus of claim 9, wherein
the 1st-2 trench includes a 1st-2-1 trench, a 1st-2-2 trench, and a 1st-2-3 trench,
the 1st-2-1 trench is formed in a portion of the first foldable area adjacent to the first non-folded area,
the 1st-2-2 trench is formed in a portion of the first foldable area adjacent to the third foldable area,
the 1st-2-3 trench is formed in a portion of the first foldable area located between the portion of the first foldable area where the 1st-2-1 trench is formed and the portion of the first foldable area where the 1st-2-2 trench is formed,
a depth of the 1st-2-3 trench is greater than a depth of the 1st-2-2 trench, and
a depth of the 1st-2-1 trench is greater than the depth of the 1st-2-3 trench.

13. The display apparatus of claim 9, wherein
the 2nd-2 trench includes a 2nd-2-1 trench, a 2nd-2-2 trench, and a 2nd-2-3 trench,
the 2nd-2-1 trench is formed in a portion of the second foldable area adjacent to the second non-folded area,
the 2nd-2-2 trench is formed in a portion of the second foldable area adjacent to the third foldable area,
the 2nd-2-3 trench is formed in a portion of the second foldable area located between the portion of the second foldable area where the 2nd-2-1 trench is formed and the portion of the second foldable area where the 2nd-2-2 trench is formed,
a depth of the 2nd-2-3 trench is greater than a depth of the 2nd-2-2 trench, and
a depth of the 2nd-2-1 trench is greater than the depth of the 2nd-2-3 trench.

14. The display apparatus of claim 8, further comprising:
a protective film disposed above the cover window; and
an upper adhesive layer disposed between the cover window and the protective film.

15. A method of manufacturing a display apparatus, the method comprising:
providing a window that includes a first non-folded area, a second non-folded area, and a foldable area located between the first non-folded area and the second non-folded area, wherein a plurality of trenches are formed in the foldable area;
attaching a release film to the window by using a release film adhesive layer;
filling a space with a protective layer composition, wherein the space is surrounded by the release film adhesive layer, the release film, and a portion of the window in which the plurality of trenches are formed;
irradiating ultraviolet light to the protective layer composition; and
removing the release film adhesive layer and the release film from the window,
wherein depths of a trench formed adjacent to the first non-folded area and a trench formed adjacent to the second non-folded area are greater than a depth of a trench formed in a central area of the foldable area.

16. The method of claim 15, wherein
the window includes a first window surface and a second window surface opposite to the first window surface,
the plurality of trenches include first trenches formed in the first window surface and second trenches formed in the second window surface, and
in a plan view, the first trenches and the second trenches are alternately arranged.

17. The method of claim 16, wherein
the foldable area includes a first foldable area adjacent to the first non-folded area, a second foldable area adjacent to the second non-folded area, and a third foldable area located between the first foldable area and the second foldable area,
the first trenches include a 1st-1 trench formed in the first foldable area, a 2nd-1 trench formed in the second foldable area, and a 3rd-1 trench formed in the third foldable area, and
a depth of the 1st-1 trench and a depth of the 2nd-1 trench are each greater than a depth of the 3rd-1 trench.

18. The method of claim 17, wherein
the second trenches include a 1st-2 trench formed in the first foldable area, a 2nd-2 trench formed in the second foldable area, and a 3rd-2 trench formed in the third foldable area, and
a depth of the 1st-2 trench and a depth of the 2nd-2 trench are each greater than a depth of the 3rd-2 trench.

19. The method of claim 16, wherein attaching the release film comprises:
attaching a first release film to the window by using a first release film adhesive layer disposed on the first window surface of the first non-folded area and the second non-folded area; and
attaching a second release film to the window by using a second release film adhesive layer disposed on the second window surface of the first non-folded area and the second non-folded area.

20. The method of claim 19, wherein filling a space with the protective layer composition comprises:
filling a first space with a first protective layer composition, wherein the first space is surrounded by the first release film adhesive layer, the first release film, and the portion of the window in which the first trenches are formed; and
filling a second space with a second protective layer composition, wherein the second space is surrounded by the second release film adhesive layer, the second release film, and the portion of the window in which the second trenches are formed.

21. The method of claim 20, wherein irradiating the ultraviolet light comprises:
forming a first protective layer by irradiating ultraviolet light onto the first protective layer composition; and
forming a second protective layer by irradiating ultraviolet light onto the second protective layer composition.

22. The method of claim 21, wherein
a portion of the first protective layer disposed below a portion of the foldable area adjacent to the first non-folded area has a first slope, and
a portion of the first protective layer disposed below a portion of the foldable area adjacent to the second non-folded area has a second slope.

23. The method of claim 21, wherein
a portion of the second protective layer disposed above a portion of the foldable area adjacent to the first non-folded area has a first slope, and
a portion of the second protective layer disposed above a portion of the foldable area adjacent to the second non-folded area has a second slope.

24. A display apparatus, comprising:
a display panel that includes display elements; and
a cover window disposed above the display panel and that includes a window, wherein the window includes a first window surface in a direction of the display panel and a second window surface in a direction opposite to the direction of the display panel, a first non-folded area, a second non-folded area, and a foldable area between the first non-folded area and the second non-folded area,
a plurality of trenches are formed in one of the first window surface or the second window surface, and
depths of a trench formed adjacent to the first non-folded area and a trench formed adjacent to the second non-folded area are greater than a depth of a trench formed in a central area of the foldable area.

25. The display apparatus of claim 24,
wherein the cover window further includes a first protective layer and a second protective layer,
wherein
the first protective layer is disposed below the foldable area,
the second protective layer is disposed on the foldable area, and
a portion of one of the first or second protective layers that corresponds to where plurality of trenches are formed has a slope.
